(19) United States
(12) Patent Application Publication
(10) Pub. No.: US 2023/0402259 A1
(43) Pub. Date: Dec. 14, 2023

(54) LOCALIZED PLASMA ARC PREVENTION VIA PURGE RING

(71) Applicant: Lam Research Corporation, Fremont, CA (US)

(72) Inventors: Karl Frederick Leeser, West Linn, OR (US); Bradley John Baker, Tualatin, OR (US); Arun Keshavamurthy, Bangalore (IN); Sassan Roham, San Ramon, CA (US)

(21) Appl. No.: 18/250,349

(22) PCT Filed: Oct. 22, 2021
(86) PCT No.: PCT/US2021/056339

§ 371 Date: Apr. 24, 2023

Related U.S. Application Data
(60) Provisional application No. 63/117,404, filed on Nov. 23, 2020.

(51) Int. Cl. H01J 37/32; C23C 16/458; C23C 16/455

(52) U.S. Cl. CPC H01J 37/32449; C23C 16/458; C23C 16/45521; H01J 37/32513

(57) ABSTRACT

A purge ring including a supply port configured for receiving gas. An outer channel is connected to the supply port. An outlet network is configured for an exit flow of the gas proximate to an inner diameter of the purge ring. The purge ring includes a plurality of channels configured for flow of the gas in a radial direction from the outer channel to the outlet network. The purge ring includes a plurality of passageways configured for reduced flow of the gas in the radial direction between the outer channel and the outlet network. The plurality of channels and the plurality of passageways are configured for providing a uniform pressure of the exit flow of the gas across the outlet network circumference.

### TECHNICAL FIELD

The present embodiments relate to semiconductor substrate processing equipment tools, and more particularly, a purge ring configured for the symmetric distribution of inert gas around a wafer perimeter.

### BACKGROUND OF THE DISCLOSURE

Improved film uniformity is important in plasma-enhanced chemical vapor deposition (PECVD) and plasma atomic layer deposition (ALD) technologies. The chamber systems implementing PECVD and ALD processes may introduce nonuniformities of various origins. In particular, multi-station modules performing PECVD and ALD feature a large, open reactor that may contribute to azimuthal nonuniformities and edge drop effects. Nonuniformities also exist in single station modules. For example, a standard pedestal configuration does not provide the desired flow profile and/or material conditions near the edge of the wafer during plasma processing. In particular, a standard pedestal configuration may produce charges on a wafer edge during PECVD and/or ALD processes, which introduces the probability of electrical discharge, or arcing, from the wafer to the ceramic pedestal during processing, which results in wafer nonuniformity and/or damage to the pedestal. As dies are pushed ever closer to the wafer edge, wafer nonuniformity at the edge has a greater negative impact on yield, for example. Despite best efforts to minimize damage to the pedestal and/or non-uniform deposition profiles, traditional PECVD and plasma ALD schemes still need improvement.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure

It is in this context that embodiments of the disclosure arise.

### SUMMARY

The present embodiments relate to solving one or more problems found in the related art, and specifically to perform semiconductor processes including providing localized dilution of a plasma sheath around a perimeter of a wafer using a ceramic purge ring configured with radial internal passageways and/or plenums designed to deliver inert gas through a distribution network or volume of secondary internal passageways and/or plenums and channels to deliver inert gas to the perimeter of the wafer in a precise and controlled mass flow rate allowing for the symmetric distribution of inert gas around the wafer perimeter. Several inventive embodiments of the present disclosure are described below.

Deposition chambers (e.g., PECVD, ALD, etc.) contain one or more stations with n radio frequency (RF) source, a wafer, and a grounded surface opposing the source. Purge rings are used to reduce and/or impede excessive charge buildup at the wafer edge during deposition processes. In embodiment of the present disclosure, a purge ring with a single gas input port provides for the reduction of charge on the wafer edge, thereby reducing the probability of electrical discharge, or arcing, from the wafer to the ceramic pedestal during deposition processing.

Embodiments of the present disclosure include a purge ring. The purge ring includes a supply port configured for receiving gas. The purge ring includes an outer channel connected to the supply port. The purge ring includes an outlet network configured for an exit flow of the gas proximate to an inner diameter of the purge ring. The purge ring includes a plurality of channels configured for flow of the gas in a radial direction from the outer channel to the outlet network. The purge ring includes a plurality of passageways configured for reduced flow of the gas in the radial direction between the outer channel and the outlet network. The plurality of channels and the plurality of passageways are configured for providing a uniform pressure and/or velocity of the exit flow of the gas across a circumference of the outlet network.

Other embodiments of the present disclosure include a pedestal assembly of a process chamber for depositing film. The pedestal assembly including a pedestal for supporting a substrate, and a purge ring configured for placement about a periphery of the pedestal. The purge ring includes a pedestal for supporting a substrate. The purge ring includes a supply port configured for receiving gas. The purge ring includes an outer channel connected to the supply port. The purge ring includes an outlet network configured for an exit flow of the gas proximate to an inner diameter of the purge ring. The purge ring includes a plurality of channels configured for flow of the gas in a radial direction from the outer channel to the outlet network. The purge ring includes a plurality of passageways configured for reduced flow of the gas in the radial direction between the outer channel and the outlet network. In the purge ring, the plurality of channels and the plurality of passageways are configured for providing a uniform pressure and/or velocity of the exit flow of the gas across a circumference of the outlet network.

Still other embodiments of the present disclosure include a process chamber. The process chamber including a plurality of stations, each station including a pedestal assembly. Each pedestal assembly including a pedestal for supporting a substrate, a purge ring configured for placement about a periphery of the pedestal, and a gas distribution system for distributing the gas with even gas flow to pedestal assemblies of each of the plurality of stations. The purge ring includes a supply port configured for receiving gas. The purge ring includes an outer channel connected to the supply port. The purge ring includes an outlet network configured for an exit flow of the gas proximate to an inner diameter of the purge ring. The purge ring includes a plurality of channels configured for flow of the gas in a radial direction from the outer channel to the outlet network. The purge ring includes a plurality of passageways configured for reduced flow of the gas in the radial direction between the outer channel and the outlet network. In the purge ring, the plurality of channels and the plurality of passageways are configured for providing a uniform pressure and/or velocity of the exit flow of the gas across a circumference of the outlet network.

These and other advantages will be appreciated by those skilled in the art upon reading the entire specification and the claims.

### BRIEF DESCRIPTION OF THE DRAWINGS

The embodiments may best be understood by reference to the following description taken in conjunction with the accompanying drawings.

FIG. 1 illustrates a substrate processing system, which is used to process a wafer, e.g., to form films thereon.

FIG. 2A illustrates a top view of a multi-station processing tool, wherein four processing stations are provided, in accordance with one embodiment.

FIG. 2B illustrates a perspective view of the multi-station processing tool of FIG. 2A, in accordance with one embodiment of the disclosure.

FIG. 3 shows a schematic view of an embodiment of a multi-station processing tool with an inbound load lock and an outbound load lock, in accordance with one embodiment.

FIG. 4A illustrates a top view of a cross-section of a purge ring configured for symmetric distribution of inert gas around a wafer perimeter, in accordance with one embodiment of the disclosure.

FIG. 4B illustrates a top view of a cross-section of a purge ring configured for symmetric distribution of inert gas around a wafer perimeter showing the flow of gas around one or more passageways, in accordance with one embodiment of the disclosure.

FIG. 4C is a table listing an exemplary number of channels and exemplary widths of the channels within a purge ring configured for symmetric distribution of inert gas around a wafer perimeter, in accordance with one embodiment of the disclosure.

FIG. 4D is a graph illustrating velocity of gas with respect to angular position on a purge ring configured for symmetric distribution of inert gas around a wafer perimeter, in accordance with one embodiment of the disclosure.

FIG. 5A is a perspective view including a cross-section of a purge ring configured for symmetric distribution of purge gas around a wafer perimeter, the purge ring including an outlet network including a plurality of orifices configured for the outflow of gas delivered from a distribution volume, in accordance with one embodiment of the disclosure.

FIG. 5B is another perspective view including a cross-section of the purge ring shown in FIG. 5A, in accordance with one embodiment of the disclosure.

FIG. 5C is a perspective view including a cross-section of a purge ring configured for symmetric distribution of inert gas around a wafer perimeter, the purge ring including an outlet network including an outlet channel configured for the outflow of gas delivered from a distribution volume, in accordance with one embodiment of the disclosure.

FIG. 5D is a perspective view including a cross-section of a purge ring configured for symmetric distribution of inert gas around a wafer perimeter, the purge ring including an outlet network including a series of outlet ports arranged on an inner ledge, the outlet ports configured for the outflow of gas delivered from a distribution volume, in accordance with one embodiment of the disclosure.

FIG. 6A-1 is a cross-section taken along line A—A of FIG. 4A of a channel in a distribution volume of a purge ring configured for symmetric distribution of inert gas around a wafer perimeter, wherein exit channels are configured in a downwards and inwards orientation, in accordance with one embodiment of the disclosure.

FIG. 6A-2 is a cross-section of a channel in a distribution volume of a purge ring configured for symmetric distribution of inert gas around a wafer perimeter, wherein exit channels are configured in a downwards and outwards orientation, in accordance with one embodiment of the disclosure.

FIG. 6A-3 is a cross-section of a channel in a distribution volume of a purge ring configured for symmetric distribution of inert gas around a wafer perimeter, wherein exit channels are configured in a upwards and inwards orientation, in accordance with one embodiment of the disclosure.

FIG. 6A-4 is a cross-section of a channel in a distribution volume of a purge ring configured for symmetric distribution of inert gas around a wafer perimeter, wherein exit channels are configured in a upwards and outwards orientation, in accordance with one embodiment of the disclosure.

FIG. 6B is a cutaway view including a cross-section of a purge ring configured for symmetric distribution of inert gas around a wafer perimeter, and shows the FIG. 6C is a cross-section taken along line B—B of FIG. 4A of a passageway in a distribution volume of a purge ring configured for symmetric distribution of inert gas around a wafer perimeter, in accordance with one embodiment of the disclosure.

FIG. 7 illustrates a gas distribution system for distributing the gas with even gas flow to pedestal assemblies of a plurality of stations within a process chamber, each of the pedestal assemblies including a purge ring configured for symmetric distribution of inert gas around a wafer perimeter, in accordance with one embodiment of the disclosure.

FIG. 8A is a cross section of a pedestal assembly including a purge ring configured for symmetric distribution of inert gas around a wafer perimeter and a conduit for delivering gas to the purge ring, in accordance with one embodiment of the disclosure.

FIG. 8B is a cross section of a coupling interface connecting a gas conduit to a ceramic purge ring configured for symmetric distribution of inert gas around a wafer perimeter and a conduit for delivering gas to the purge ring, in accordance with one embodiment of the disclosure.

FIG. 8C is a cross section of a flow resistor configured within a conduit for delivering gas to a purge ring that is configured for symmetric distribution of inert gas around a wafer perimeter and a conduit for delivering gas to the purge ring, in accordance with one embodiment of the disclosure.

FIG. 8D is a cross section of a pedestal assembly including a purge ring configured for symmetric distribution of inert gas around a wafer perimeter, in accordance with one embodiment of the disclosure.

FIG. 9A illustrates a top view of a multi-station processing tool, wherein four processing stations are provided, and shows a gas distribution system for distributing the gas with even gas flow to pedestal assemblies of each of the plurality of stations, in accordance with one embodiment of the disclosure.

FIG. 9B illustrates a top view of chamber inserts of a multi-station processing tool, wherein four processing stations are provided, and shows the gas distribution system of FIG. 9A routed through openings in station partition walls of the chamber, in accordance with one embodiment of the disclosure.

FIG. 9C illustrates a bottom view of chamber inserts of a multi-station processing tool, wherein four processing stations are provided, and shows the gas distribution system of FIG. 9A routed through openings in station partition walls of the chamber, in accordance with one embodiment of the disclosure.

FIG. 10 shows a control module for controlling the systems described above.

### DETAILED DESCRIPTION

Although the following detailed description contains many specific details for the purposes of illustration, anyone of ordinary skill in the art will appreciate that many variations and alterations to the following details are within the scope of the present disclosure. Accordingly, the aspects of the present disclosure described below are set forth without any loss of generality to, and without imposing limitations upon, the claims that follow this description.

Generally speaking, the various embodiments of the present disclosure describe systems that provide for improved film uniformity during wafer processing (e.g., PECVD and ALD processes) in single-station and multi-station systems. In particular, various embodiments of the present disclosure describe pedestal assemblies that include a ceramic purge ring that provides for localized dilution of a plasma sheath around a perimeter of a wafer, wherein the purge ring is designed to deliver precise amounts of inert gas flow during a deposition process. Through the purge ring, sufficient inert mass gas flow is introduced at the perimeter of the wafer, such as during a plasma enhanced chemical vapor deposition (PECVD) process, that impedes excessive charge buildup at the wafer edge. The PECVD process is used to deposit thin films on the substrate through chemical reactions of gases creating a plasma. In that manner, this reduction of charge on the wafer edge thereby reduces the probability of electrical discharge, or arcing, from the wafer to the ceramic pedestal during process, which in some implementations increases wafer uniformity, especially at the edge of the wafer. In particular, the purge ring is composed of high temperature ceramic that is configured to withstand temperatures in the range of 650° C. in order for the purge ring to deliver inert gas to the wafer perimeter. The ceramic purge ring geometry utilizes laminated ceramic technology to create a distribution of internal radial passageways and/or plenums for delivery of inert gas to a distribution volume of secondary internal passageways and/or plenums & channels. These internal channels are formed using laminated ceramic technology, and form the geometry for variable flow paths for the inert gas. In one embodiment, a precise pattern of orifices around the perimeter of the ring delivers the inert gas to the perimeter of the wafer in a precise and controlled mass flow rate. In one embodiment, one inert gas supply port is provided for efficiency inside the process chamber. Heretofore, the mass flow distribution inside the purge ring with one inert gas supply port would be highly asymmetric in nature, with high gas flow near the supply port, and diminishing gas flow around the purge ring until reaching a point opposite the supply port. However, embodiments of the present disclosure provide for a purge ring configured for variable flow of gas around the perimeter of the purge ring. In particular, the purge ring of embodiments of the present disclosure is configured to provide a fluid variable flow approach which corrects the mass flow distribution to a symmetric distribution around the wafer perimeter. This is achieved through the design of multiple internal flow and/or conductance channels, one or more orifices allowing for the exiting of the gas, selection of the proper type of orifice and/or orifices, selection of a desirable number of orifice and/or orifices, orifice shape, size and diameter, etc. In still other embodiments, in addition to arc suppression embodiments of the present disclosure may possibly be utilized for prevention of backside carbon deposition by dilution of C3H6.

Advantages of the various embodiments, disclosing process chambers including one or more pedestal assemblies of one or more stations and including corresponding purge rings configured for symmetric distribution of inert gas around a wafer perimeter (e.g., deliver flow of gas at uniform pressure azimuthally along wafer perimeter and/or deliver flow of gas with uniform velocity or speed azimuthally along the wafer perimeter) provide for more economical and more efficient delivery of gas to the one or more stations within the process chamber. In addition, each of the purge rings provide for a more efficient delivery of gas in a purge ring using a single supply port (e.g., purge inlet) and proper configuration of a distribution volume of passageways and channels to a wafer perimeter.

With the above general understanding of the various embodiments, example details of the embodiments will now be described with reference to the various drawings. Similarly numbered elements and/or components in one or more figures are intended to generally have the same configuration and/or functionality. Further, figures may not be drawn to scale but are intended to illustrate and emphasize novel concepts. It will be apparent, that the present embodiments may be practiced without some or all of these specific details. In other instances, well-known process operations have not been described in detail in order not to unnecessarily obscure the present embodiments.

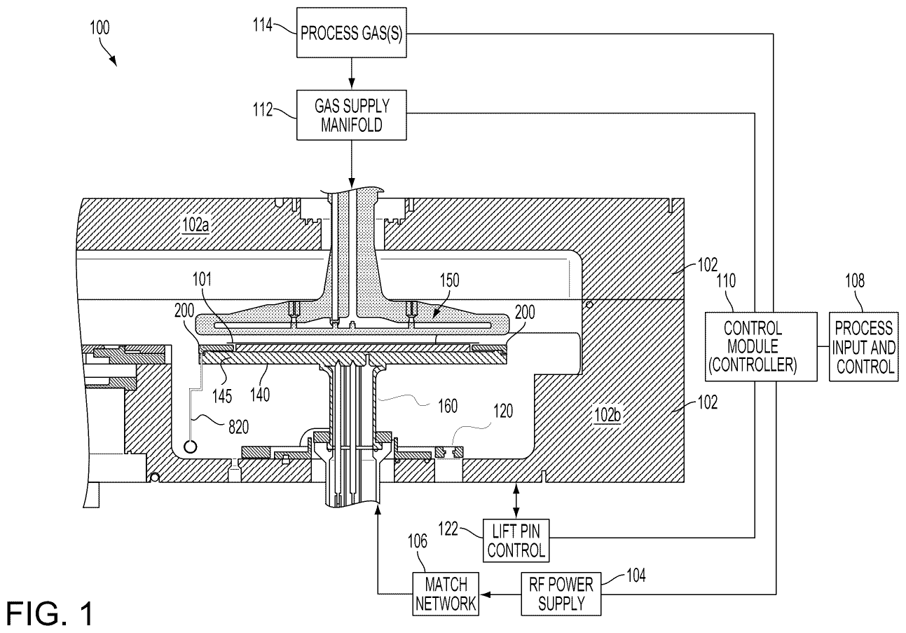

FIG. 1 illustrates a reactor system 100, which may be used to deposit films over substrates, such as those formed in PECVD or ALD processes. More particularly, FIG. 1 illustrates a substrate processing system 100, which is used to process a wafer 101. The system includes a chamber 102 having a lower chamber portion 102b and an upper chamber portion 102a. A center column is configured to support a pedestal 140, which in one embodiment is a powered electrode. The pedestal 140 is electrically coupled to power supply 104 via a match network 106. The power supply is controlled by a control module 110, e.g., a controller. The control module 110 is configured to operate the substrate processing system 100 by executing process input and control 108. The process input and control 108 may include process recipes, such as power levels, timing parameters, process gasses, purge gasses to a purge ring, mechanical movement of the wafer 101, etc., such as to deposit or form films over the wafer 101.

The center column (e.g., also known as central shaft or spindle) 160 may interface with lift pins (not shown), each of which is actuated by a corresponding lift pin actuation ring 120 as controlled by lift pin control 122. The lift pins are used to raise the wafer 101 from the pedestal 140 to allow a robot arm (e.g., an end-effector, etc.) to deliver (e.g., load) a wafer to the process chamber and/or to remove (e.g., unload) a wafer from the process chamber 250. In one embodiment, a ringless wafer delivery system is implemented that is configured for wafer transfer between stations without the use of a carrier ring, for example. The substrate processing system 100 further includes a gas supply manifold 112 that is connected to process gases 114, e.g., gas chemistry supplies from a facility. Depending on the processing being performed, the control module 110 controls the delivery of process gases 114 via the gas supply manifold 112. The chosen gases are then flown into the shower head 150 and distributed in a space volume defined between the showerhead 150 face that faces that wafer 101 and the wafer 101 resting over the pedestal 140. In ALD processes, the gases can be reactants chosen for absorption or reaction with absorbed reactants.

Further, the gases may be premixed or not. Appropriate valving and mass flow control mechanisms may be employed to ensure that the correct gases are delivered during the deposition and plasma treatment phases of the process. Process gases exit chamber via an outlet. A vacuum pump (e.g., a one or two stage mechanical dry pump and/or a turbomolecular pump) draws process gases out and maintains a suitably low pressure within the reactor by a close loop controlled flow restriction device, such as a throttle valve or a pendulum valve.

Also shown is a purge ring 200 that encircles an outer and/or peripheral region of the pedestal 140. In one embodiment, the purge ring 200 is positioned below a wafer 101 disposed on the pedestal 140, as is shown in FIG. 1. The purge ring 200 supplies a purge gas (e.g., inert gas, nitrogen, etc.) to the wafer edge and is designed to reduce and/or impede excessive charge buildup at the wafer edge during deposition processes. The purge gas is delivered from the gas supply line 840 that is connected to a gas delivery system. In one embodiment, the purge ring 200 remains within a station, and is not rotated from station to station, e.g., in a multi-station processing chamber and/or system. In other embodiments, the chamber is a single station chamber. Controller 110 and/or process input and control 108 may be used to control the delivery of the purge gas to the purge ring.

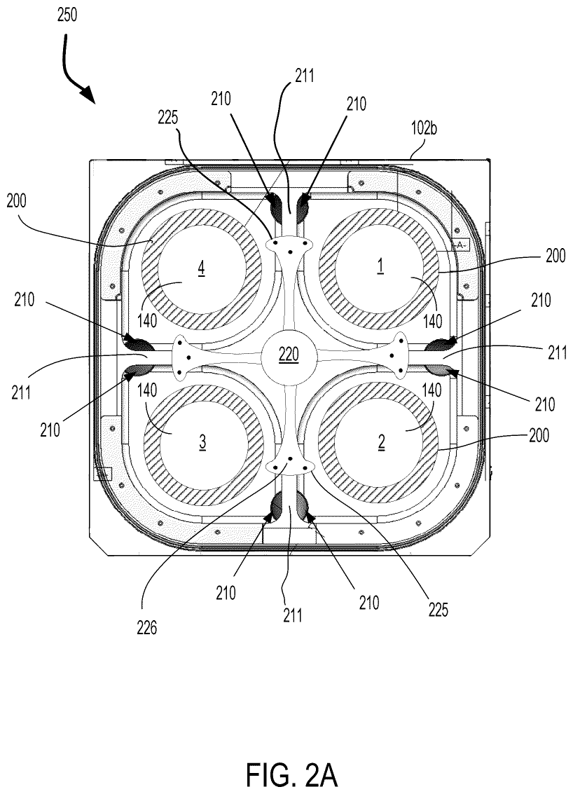

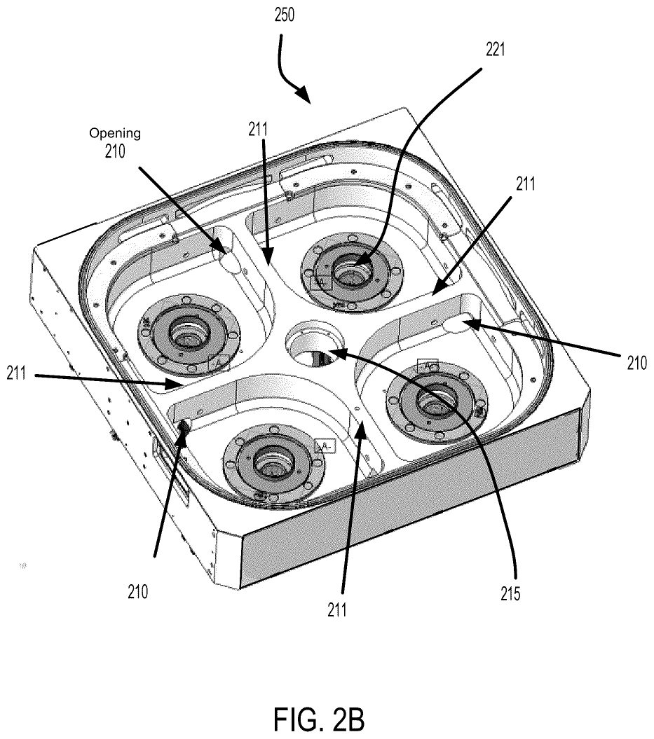

FIG. 2A illustrates a top view of a multi-station processing tool 250, wherein four processing stations are provided. This top view is of the lower chamber portion 102b (e.g., with the top chamber portion 102a removed for illustration), wherein four stations (e.g., stations 1, 2, 3, and 4) may be accessed by a ringless wafer delivery system that is configured for wafer transfer between stations without the use of a carrier ring, for example. The ringless wafer delivery system includes one or more paddles 225, each of which is configured for interfacing with a corresponding wafer that is lifted from the pedestal, for example using lift pins. The ends of the paddles 225 may include three kinematic wafer contact pads 226 configured for interfacing with the underside of a wafer, such as when transferring the wafer from one station to another station. The ends of the paddles 225 may be articulated to provide for additional movement when orienting a corresponding paddle under a corresponding wafer. Each paddle may be rotated using a rotation mechanism 220 (e.g., in unison), such that wafers introduced into the chamber 250 to a station (e.g., loading and/or unloading a wafer between station 1 and a load lock using a robot arm) may be transferred and/or rotated from station to station using the ringless wafer delivery system, so that further plasma processing, treatment and/or film deposition, wafer delivery and/or removal can take place on respective wafers 101.

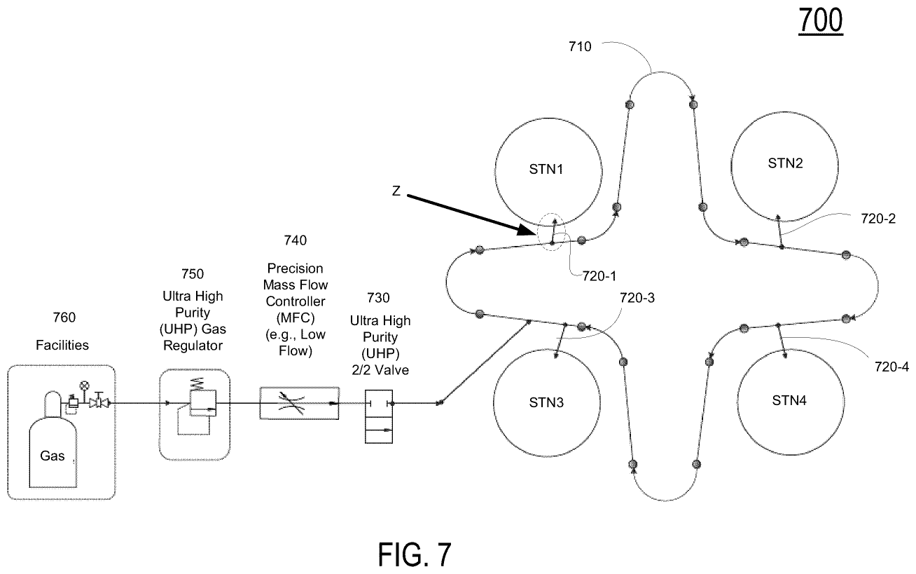

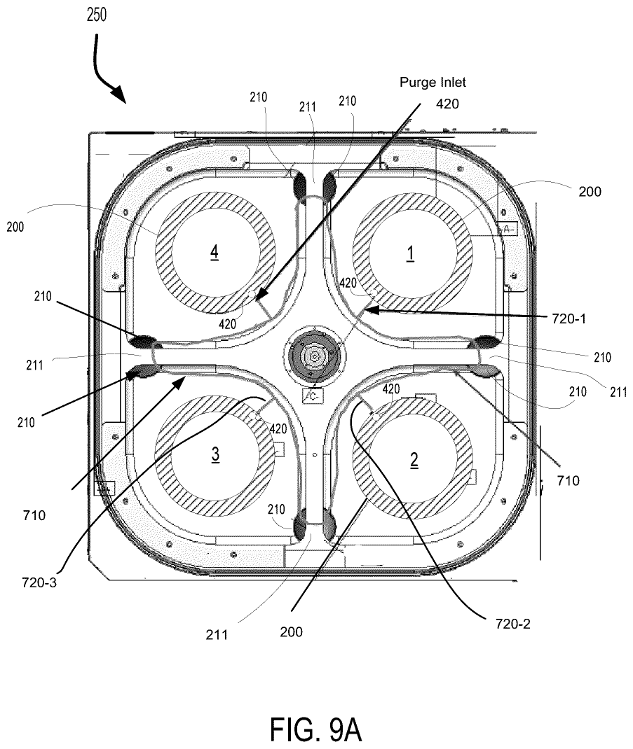

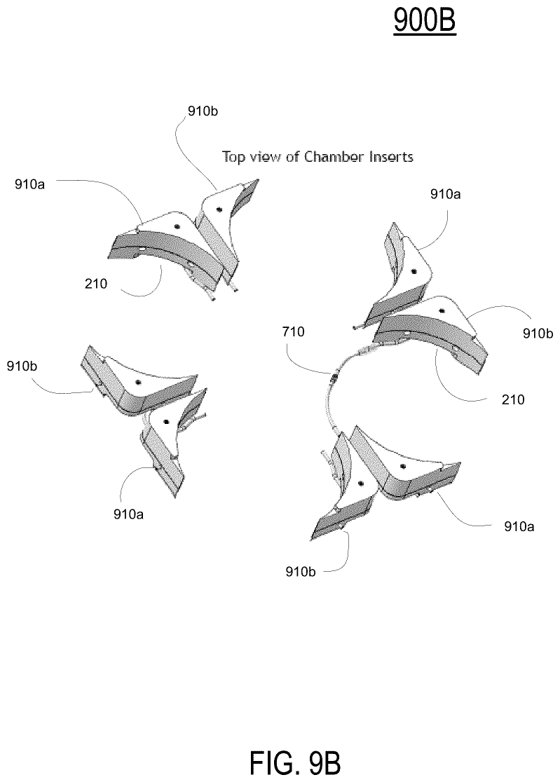

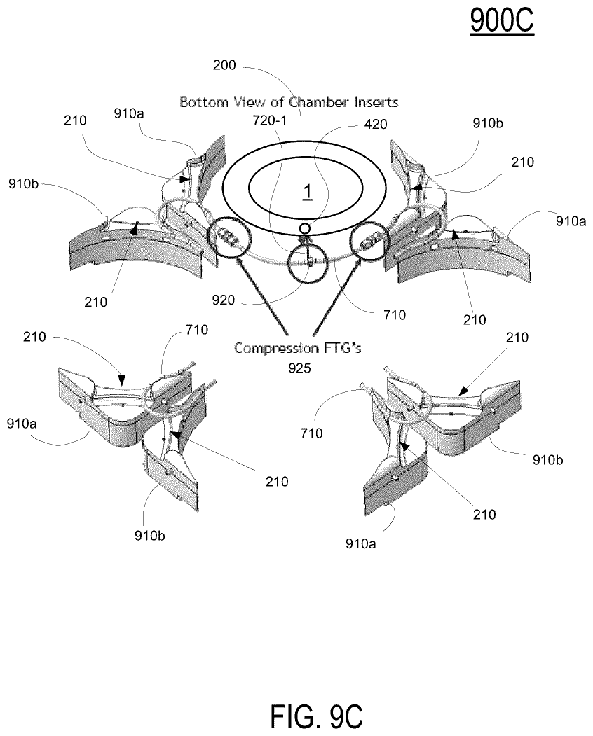

Openings 210 are shown within station partition walls 211 of the multi-station processing tool 250, wherein the walls 211 provide separation for each of the stations. In one embodiment, the openings 210 may be used for routing a gas supply conduit or gas delivery structure 710 within the multi-station processing tool, as will be further described below with reference to FIGS. 9A-9C. The gas supply conduit 710 is included within a gas distribution system that is utilized to deliver the purge gas to each of the stations, as is further described with reference to FIG. 7.

FIG. 2B illustrates a perspective view of the multi-station processing tool 250 introduced in FIG. 2A, in accordance with one embodiment of the disclosure. More particularly, the lower chamber portion 102b is shown without a pedestal assembly (e.g., pedestal 140, purge ring 200, spindle 160, etc.) to provide an unobstructed view to the inner volume of each station. For example, openings 210 are clearly shown in FIG. 2B. Also, each station (e.g., 1, 2, 3, and 4) includes a station connection 221 configured for seating a spindle 160 (e.g., central shaft) of the pedestal 140. Also, center hole 215 is shown and configured for receiving the rotation mechanism that is used for indexing a wafer to a particular station.

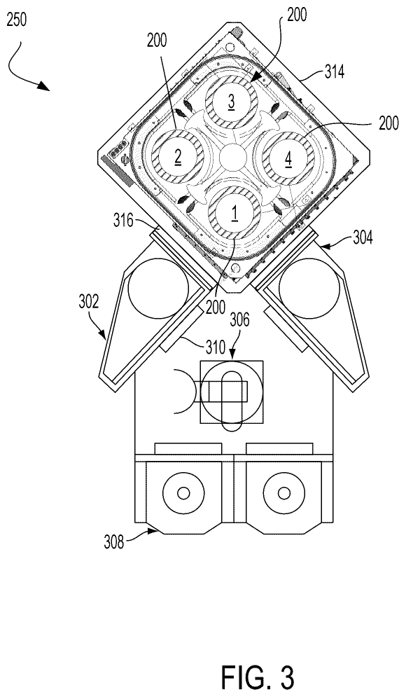

FIG. 3 shows a schematic view of an embodiment of the multi-station processing tool 250 of FIGS. 2A-2B with an inbound load lock 302 and an outbound load lock 304. A robot 306, at atmospheric pressure, is configured to move substrates from a cassette loaded through a pod 308 into inbound load lock 302 via an atmospheric port 310. Inbound load lock 302 is coupled to a vacuum source (not shown) so that, when atmospheric port 310 is closed, inbound load lock 302 may be pumped down. Inbound load lock 302 also includes a chamber transport port 316 interfaced with processing chamber 102b. Thus, when chamber transport 316 is opened, another robot (not shown) (e.g., ringless wafer delivery system) may move the substrate from inbound load lock 302 to a pedestal 140 of a first process station for processing.

The depicted multi-station processing chamber 250 includes four process stations, numbered from 1 to 4 in the embodiment shown in FIG. 3. Each of the process stations depicted in FIG. 3 includes a purge ring 200 and process gas delivery line inlets or purge inlets (not shown). The purge ring is configured to reduce and/or impede excessive charge buildup at the wafer edge during deposition processes. The reduction of charge on the wafer edge thereby reduces the probability of electrical discharge, or arcing, from the wafer to the ceramic pedestal during process, which in turn increases wafer uniformity, especially at the edge of the wafer

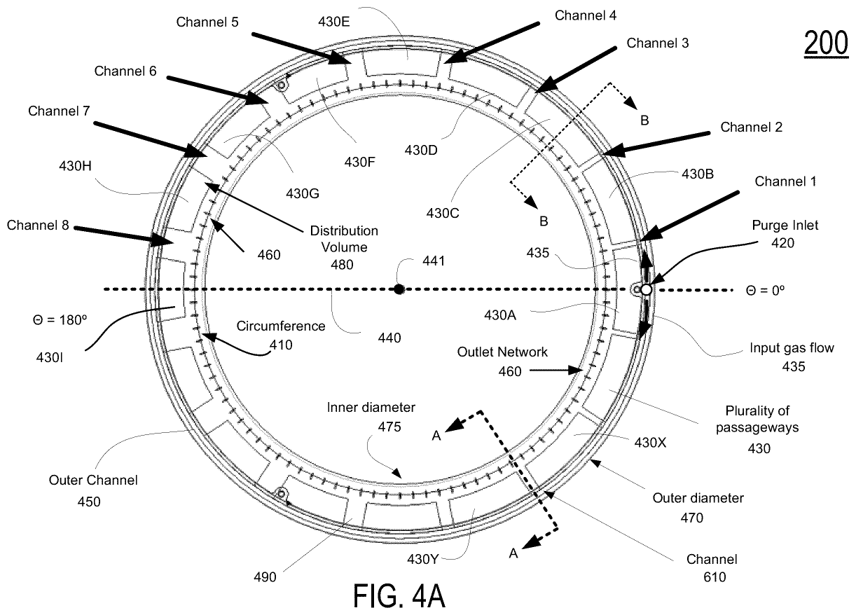

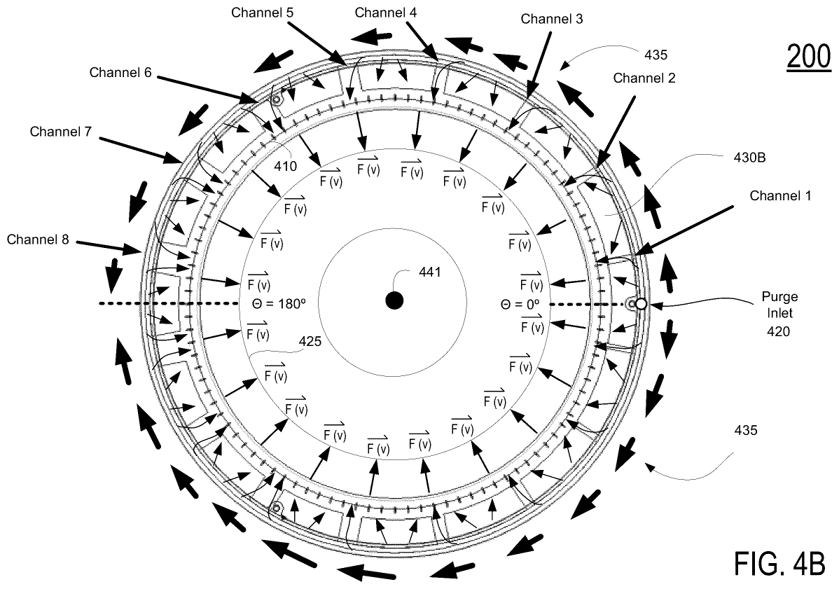

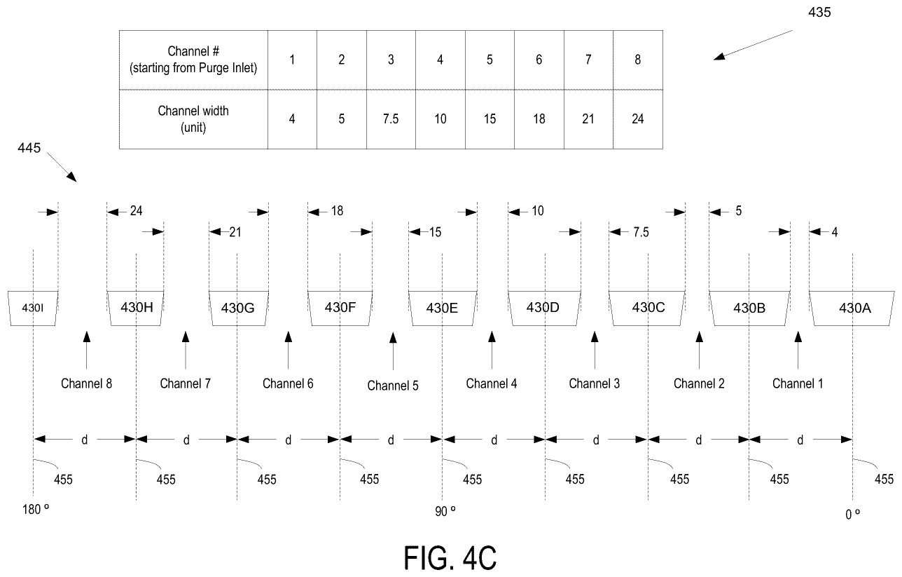

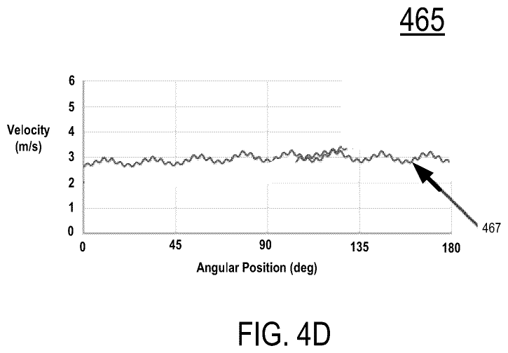

FIG. 4A illustrates a top view of a horizontal cross-section of the purge ring 200, in accordance with one embodiment of the disclosure. The purge ring 200 is configured for symmetric and radial distribution of purge gas (e.g., inert gas) around a wafer perimeter, in embodiments of the disclosure. In particular, the purge ring 200 is configured to dilute a plasma sheath around the perimeter of the wafer during processing (e.g., deposition), and is configured to deliver gas through passageways and channels radially throughout the purge ring with symmetric flow at all points around a circumference 410 of the purge ring, wherein the circumference may be aligned with an outlet network configured for the outflow of gas to the wafer perimeter. Specifically, the purge ring is configured to deliver flow of gas at uniform pressure azimuthally along wafer perimeter and/or deliver flow of gas with uniform velocity or speed azimuthally along the wafer perimeter.

The purge ring 200 is configured for delivery of gas (e.g., purge gas, inert gas, nitrogen, N2, vapor, etc.) to an edge of a wafer (not shown) under extreme conditions (e.g., high temperature, high pressure, etc.). In one embodiment, the purge ring 200 includes a single supply port or purge inlet 420 that is configured for receiving gas from a gas distribution system (not shown). The purge ring 200 is configured to provide sufficient flow of purge gas to displace processes gases (e.g., argon, C3H6, etc.) at the wafer edge during processing (e.g., deposition), and more particularly to prevent arcing (e.g., electrical discharge) to the pedestal from the wafer edge. That is, arcing due to static discharge from the wafer to pedestal is reduced and/or eliminated by reducing the process gases at the wafer edge with the introduction of the purge gas at the wafer edge.

As shown in FIG. 4A, the purge ring 200 includes a supply port or purge inlet 420 that is configured for receiving gas (e.g., purge gas, inert gas, nitrogen, etc.), wherein in some embodiments the gas is in the form of a vapor. Also, the purge ring includes an outer channel 450 that is connected to the supply port 420. In one embodiment, the outer channel 450 is configured proximate to an outer diameter 470 of the purge ring 200. The outer channel 450 distributes the purge gas around the perimeter of the purge ring in a first phase of gas distribution. For example, the outer channel 450 presents a low fluid resistance to allow for circumferential flow of the purge gas throughout the outer channel. In that manner, the gas reaches pressure equilibrium in the outer channel 450 before entering or leaking radially into a plurality of channels and a plurality of passageways in a second phase of gas distribution. That is, the outer channel 450 is configured to achieve pressure equilibrium before radial flow of the gas to the outlet network occurs. As shown, the input gas flow 435 provided as input from the purge inlet 420 flows in opposing directions in the outer channel 450. That is, the gas after entering in the purge ring 200 from the purge inlet 420 flows in a counter clockwise direction from the purge inlet (e.g., towards the upper half of the purge ring 200) in the outer channel 450, and also flows in a clockwise direction (e.g., towards the lower half of the purge ring 200) in the outer channel 450.

The purge ring 200 includes an outlet network 460 configured for an exit flow of the gas proximate to an inner diameter 475 of the purge ring 200. For example, the outlet network 460 may be of any configuration that provides for symmetric outflow of gas at all points around the wafer edge. That is, the pressure of the gas is uniform throughout the outlet network 460 to provide for the symmetric outflow of gas. That is, the flow of gas is delivered at uniform pressure azimuthally along a wafer perimeter (e.g., circumference of the purge ring) and/or the flow of gas is delivered with uniform velocity or speed azimuthally along the wafer perimeter. The even distribution of the gas to the wafer edge helps to prevent arcing at all points of a perimeter of a pedestal from the wafer edge of static discharge that can build up on the wafer edge from process gases. In some cases, this allows for uniform film deposition during processing throughout a wafer, including regions proximate to the wafer edge.

The purge ring includes a plurality of channels 490 and plurality of passageways 430 connecting the outer channel 450 and the outlet network 460. The channels and passageways are configured for evenly distributing purge gas to the outlet network 460 around a circumference 410 that is associated with the outlet network 460. Specifically, the channels and passageways are configured to provide radial and symmetric flow of purge gas at all points of a circumference 410 that defines the outlet network 460, wherein the circumference is located proximate to the inner diameter 475 of the purge ring 200. That is, the channels and passageways deliver the gas with uniform gas flow to all points in the circumference 410 associated with the outlet network 460. More specifically, the channels and passageways are configured for providing a uniform pressure of the exit flow of the gas azimuthally around the circumference 410 of the outlet network 460 (e.g., at delivery points). Correspondingly, the channels and passageways are configured for providing a uniform speed (e.g., magnitude of velocity) of the exit flow of the gas around or across the circumference 410 of the outlet network 460. In that manner, the outlet network 460 is able to deliver the gas to the wafer edge radially and symmetrically in a uniform manner That is, embodiments of the present disclosure provide for the delivery of gas at uniform pressure and/or velocity azimuthally around the circumference of the purge ring that is configured with asymmetric geometry. For example, pressure can be calculated so that the gas delivered by the purge ring could overcome the adverse pressure gradient to avoid backside deposition on the wafer.

In one embodiment, the purge ring 200 is symmetrically configured about line 440, such that channels and passageways are symmetrically configured between the two halves of the purge ring defined by symmetry line 440. More particularly, line 440 may be representative of a symmetrical plane about which the two halves (e.g., above and below the plane) of the purge ring 200 is symmetrically configured. As shown, symmetry line 440 (that may represent a symmetry plane) may define radials that originate at a center 441. For example, the purge inlet 420 sits on a radial of 0 degrees on line 440. Also, opposite the purge inlet 420, line 440 defines a radial of 180 degrees (e.g., the center of passageway 430I).

In particular, in the plurality of passageways 430, each passageway is configured for reduced flow of the gas in the radial direction between the outer channel and the outlet network. That is, a passageway restricts the radial flow of the gas to the outlet network 460. For example, a passageway blocks, redirects, and/or restricts the free flow of purge gas within and in and about the passageway. In one embodiment, a passageway comprises a plenum including structures configured for reduced flow of the gas. In another embodiment, a passageway comprises a porous media, wherein a porous media can be defined as any media that has pores (e.g., holes, etc.). In still another embodiment, portions of the passageway comprise a solid media. As shown in FIG. 4A, the center of passageway 430A is located at 0 degrees on line 440. Additional passageways are configured within the purge ring 200. In addition to passageway 430A, moving in a counter clockwise direction, the purge ring 200 includes passageway 430B, passageway 430C, passageway 430D, passageway 430F, passageway 430G, passageway 430H, and passageway 430I. More particularly, the center of passageway 430I is located at 180 degrees online 440.

In one embodiment, the passageways in the plurality of passageways 430 decrease in size (e.g., radial width) when moving radially around the circumference 410 of the purge ring 200 until reaching a point (e.g., 180 degrees) in the circumference that is opposite the supply port or purge inlet 420. In particular, a radial width of a first passageway that is centered at a radial distance from the purge ring inlet is smaller than a radial width of a second passageway that is centered at a radial distance that is closer to the purge ring inlet. For example, the radial width of passageway 430I is smaller than the radial width of at least one of passageway 430H, or passageway 430G, or passageway 430F, or passageway 430E, or passageway 430D, or passageway 430C, or passageway 430B. Because of the symmetrical constraints about the symmetry line and/or plane 440, passageway 430A may be smaller than at least one of the passageway 430I, or passageway 430H, or passageway 430G, or passageway 430f, or passageway 430E, or passageway 430D, or passageway 430C, or passageway 430B.

In one embodiment, at least some of the centers of the passageways may be evenly distributed (e.g., radially distributed in symmetric fashion) throughout the circumference 410 of the purge ring 200. In another embodiment, the passageways are distributed asymmetrically about the circumference 410 of the purge ring 200.

As previously described, the purge ring 200 may exhibit symmetry about symmetry line 440, which may define a symmetrical plane about which the two halves of the purge ring may be identical. As such, the bottom half of the purge ring 200 located below symmetry line 440 and/or symmetry plane is similarly configured as the upper half of the purge ring 200 located above symmetry line and/or plane 440 described above, beginning with the center of passageway 430A located at 0 degrees and ending at the center of the passageway 430I located at 180, moving in a clockwise direction. That is, passageways above symmetry line and/or plane 440 may be similarly configured as passageways located below symmetry line and/or plane 440.

The spacing between two passageways defines a channel. In particular, the purge ring 200 includes a plurality of channels 490, wherein each channel is configured for flow of the gas in a radial direction from the outer channel 450 to the outlet network 460. For example, a channel is configured for unrestricted flow of the gas from the outer channel 450 to the outlet network 460. As shown, channel 1 is formed between passageways 430A and 430B, channel 2 is formed between passageways 430B and 430C, channel 3 is formed between passageways 430C and 430D, channel 4 is formed between passageways 430D and 430E, channel 5 is formed between passageways 430E and 430F, channel 6 is formed between passageways 430F and 430G, channel 7 is formed between passageways 430G and 430H, and channel 8 is formed between passageways 430H and 430I.

In one embodiment, the passageways are configured such that the width (e.g., radial width) of the channels increase in size radially based on distance from the purge inlet 420. In particular, channels increase in size radially when moving radially around the circumference 410 of the purge ring until reaching a point (e.g., 180 degrees) in the circumference that is opposite the supply port or purge inlet 420. That is, channels that are nearer to the purge inlet 420 (e.g., less than 90 degrees from the purge inlet 420 located at 0 degrees) have less width (e.g., radial width) than channels that are further (e.g., more than 90 degrees from the purge inlet 420 located at 0 degrees) from the purge inlet 420. In particular, a radial width of a first channel that is centered at a radial distance from the purge ring inlet is larger than a radial width of a second channel that is centered at a radial distance that is closer to the purge ring inlet. For example, the radial width of channel 8 is larger than the radial width of at least one of channel 7, or channel 6, or channel 5, or channel 4, or channel 3, or channel 2, or channel 1.

In one embodiment, the channels are distributed symmetrically about the circumference 410 of the purge ring 200 (e.g., at least some of the centers of channels may be equidistant from each other). In another embodiment, the channels are distributed asymmetrically about the circumference 410 of the purge ring 200.

In some embodiments, the plurality of channels and plurality of passageways are configured within a distribution volume 480 that connects the outer channel 450 and the outlet network 460. The distribution volume is configured for evenly distributing purge gas to the outlet network 460 around a circumference 410 that is associated with the outlet network 460. Specifically, the distribution volume 480 is configured to provide radial and symmetric flow of purge gas at all points of a circumference 410 that defines the outlet network 460, wherein the circumference is located proximate to the inner diameter 475 of the purge ring 200. That is, the distribution volume 480 delivers the gas with uniform gas flow to all points in the circumference 410 associated with the outlet network 460. In that manner, the outlet network 460 is able to deliver the gas to the wafer edge radially and symmetrically in a uniform manner.

As previously described, the gas provided as input to the purge ring 200 at the purge inlet 420 first flows throughout the outer channel 450 in the first phase. For example, the input gas flow 435 flows in opposing directions in the outer channel 450 from the purge inlet 420, as previously described. As such, the input gas flow 435 flows throughout the outer channel 450 until reaching pressure equilibrium, at which point the purge gas radially leaks into the channels and passageways in a second phase. A further discussion of the operation of channels and passageways individually and in combination in the second phase is provided in FIG. 4B, which illustrates a top view of a cross-section of a purge ring 200 configured for symmetric distribution of gas (e.g., purge gas, inert gas, N2, nitrogen, etc.) around a wafer perimeter, in accordance with one embodiment of the disclosure. In particular, the plurality of passageways 430 and plurality of channels 490 are configured to provide a uniform pressure and/or velocity of the exit flow of the gas across the circumference 410 of the outlet network 460.

FIG. 4B illustrates the flow of gas around one or more passageways, in accordance with one embodiment of the disclosure. A passageway is configured to block, redirect, and/or restrict the free flow of purge gas within the passageway. For example, the gas is shown to enter each of the plurality of passageways 430 from the outer channel 450, wherein the passageways are each configured for reduced flow of the gas in the radial direction between the outer channel 450 and the outlet network 460. For example, the flow of gas may be primarily in a non-radial direction within each of the passageways. That is, the flow of gas at a corresponding passageway may not follow a direct path to the outlet network 460, such as in a direction towards the center 441 of the purge ring 200. Instead, the gas flows in various directions within the corresponding passageway, as is shown by the arrows at each passageway showing the redirection of the gas, such as towards adjacent channels. For example, the passageway 430B between channel 1 and channel 2 shows that the gas is redirected towards both of the adjacent channels. Also, some of the gas may be directed more or less towards the outlet network 460, such as towards the center of the purge ring, depending on the configuration of the passageway.

Also, in the second phase, with the open channel design, the flow of gas through each of the channels is unrestricted, such that the purge gas flows freely and/or directly towards the outlet network 460, such as towards the center of the purge ring 200. That is, the channels are configured for flow of gas in the radial direction from the outer channel 450 to the outlet network 460.

As such, the plurality of passageways 430 and plurality of channels in the distribution volume 480, as well as the configuration of the passageways and channels within the distribution volume provides for symmetric and balanced radial flow of the purge gas throughout the circumference 410 associated with the outlet network 460 of the purge ring 200 using only one supply port or purge inlet 420. Without the configuration of the passageways and/or channels, there would be asymmetric distribution of the gas throughout the purge ring, such as high flow of gas from exit ports of the outlet network 460 nearer to the purge inlet 420 (e.g., within 90 degrees of the purge inlet), and lower flow of gas from exit ports of the outlet network that are further away from the purge inlet 420 (e.g., further than 90 degrees from the purge inlet).

However, with the configuration of the passageways and/or channels (e.g., multiple internal flow and/or conductance channels, one or more exit apertures or exit ports of the outlet network, shapes of the exit apertures or exit ports, etc.) of embodiments of the present disclosure, the purge ring 200 provides for symmetric and balanced radial flow of the gas, using one supply port or purge inlet 420. Specifically, the configuration of passageways and/or channels provides for variable flow of fluid throughout the purge ring in order to provide for symmetric radial distribution of gas about the inner diameter 475 of the purge ring 200, and more specifically, about the circumference 410 associated with the outlet network 460 of the purge ring 200.

In particular, a plurality of vectors F(v) is presented about the inner diameter 475 of the purge ring 200. Each of the vectors may originate at a corresponding point on the circumference 410 associated with the outlet network 460, and have a direction that is pointed towards the center 441 of the purge ring 200. That is, each vector F(v) originates at the outlet network, such as at a corresponding exit aperture, orifice, exit port, or opening, and has a corresponding direction pointed towards the center 441. As such, the vectors F(v) are distributed about the circumference 410 of the purge ring associated with the outlet network 460

In addition, the configuration of the passageways and/or channels provide for symmetric radial distribution of gas from the outlet network. That is, the flow of gas at each point in the circumference 410 associated with the outlet network 460 is uniform, such that the magnitude of each of the plurality of vectors F(v) is approximately equal. For example, the velocity circle 425 shows approximately equal velocities (e.g., magnitudes) for all the vectors F(v), wherein the distance along each vector between the circumference 410 and the velocity circle 425 is approximately equal at all radial lines of the purge ring 200. That is, each of the vectors F(v) have approximately the same velocity. As previously introduced, each of the vectors F(v) indicate flow velocity of the gas and direction towards the center of the purge ring. In that manner, the gas is delivered to the perimeter of the wafer in a precise, controlled and uniform manner That is, the mass flow rate or radial flow velocity of the gas is uniform at all points in the circumference 410 of the outlet network 460, such that the purge ring 200 provides for radial symmetric flow of the gas. Specifically, embodiments of the present disclosure provide for the delivery of gas at uniform pressure and/or velocity azimuthally around the circumference of the purge ring.

FIG. 4C illustrates a table 435 listing an exemplary number of channels and exemplary widths of the channels within a purge ring 200 that is configured for symmetric distribution of gas around a wafer perimeter and a reprojection of passageways and channels of the purge ring, wherein the purge ring is configured for radial symmetric flow, in accordance with one embodiment of the disclosure. Although, table 435 shows a purge ring having 8 channels (e.g. in one half about a symmetric line and/or plane that is not shown) for purposes of illustration, other embodiments support purge rings having a greater or lower number of channels.

In particular, table 435 shows varying thicknesses of the channels on both sides of the symmetric line and/or symmetric plane. For purposes of discussion, channels 1-8 as shown in FIGS. 4A and 4B will be discussed and be representative of channels on both sides of the symmetric line 440 and/or symmetric plane. In one embodiment, the multi-sized channels help reduce the variation of radial flow of purge gas so that the flow of purge gas remains uniform at all angular positions around the purge ring 200, such as around the circumference 410 associated with the outlet network 460.

Reprojection 445 shows a horizontal layout of channels 1-8, and illustrates the varying widths (e.g., radial widths) of the channels. In particular, channels nearer to the purge inlet 420 (located at 0 degrees) are smaller in radial width than channels that are further from the purge inlet 420, such as those closer to an opposite point (e.g., at 180 degrees) of the purge inlet 420, as previously described. Also, reprojection 445 shows a plurality of passageways 430 (e.g., passageways 430A . . . 430I), wherein passageway 430A is centered about 0 degrees, and passageway 430I is centered about 180 degrees.

In one embodiment, at least some of the centers of each of the passageways are equidistant from each other (e.g. distance “d”), including at least passageways 430B, 430C, 430D, 430F, 430G, and 430H, as previously described. That is, centers of the plurality of passageways may be evenly distributed radially throughout the circumference 410 associated with the outlet network 460 of the purge ring 200, in one embodiment. In another embodiment, the passageways are distributed asymmetrically. Also, the channels (e.g., channels 1-8) may be distributed symmetrically or asymmetrically throughout the circumference 410.

In one embodiment, the channels increase in size (e.g., radial width) when moving radially around the circumference of the purge ring until reaching a point in the circumference that is opposite the supply port or purge inlet 420, as previously described. For purposes of illustration, channel 1 that is closest to the purge inlet 420 has a width of 4 units. On the other hand, channel 8 that is furthest from the purge inlet 420 has a width of 24 units. Channels located radially between channels 1 and 8 have corresponding widths based on the radial distance from the purge inlet 420. That is channels that are further from the purge inlet 420 are larger in width than channels that are closer to the purge inlet 420, as is shown by table 435. In particular, a radial width of a first channel centered at a radial distance from the purge ring is larger than a radial width of a second channel centered at a radial distance that is closer to the purge ring inlet.

The increase in the size of channels moving further away from the inlet port 420 is designed to promote increased flow of gas (e.g., mass flow distribution) circumferentially within the purge ring 200, and more specifically in the outlet network 460, at points that are further away from the purge inlet 420 in order to provide for the symmetric distribution of gas (e.g., even mass flow distribution) around a wafer perimeter, or in other words, even and uniform gas flow at all points around the circumference 410 associated with the outlet network 460. Traditionally, without the passageways and/or channel configurations of embodiments of the present disclosure, the mass flow distribution inside a purge ring would be highly asymmetric with higher gas flow nearer to the purge inlet, and very low gas flow at points opposite the purge inlet. However, the passageways and/or channel configurations of embodiments of the present disclosure provide for uniform mass flow distribution throughout the purge ring 200 and outlet network 460, to provide for even and uniform gas flow across all points of a circumference 410 associated with the outlet network 460 of the purge ring 200, such that there is a symmetric distribution of gas around a wafer perimeter.

Correspondingly, because channels increase in size as the channels move further away in a radial direction from the purge inlet 420, the size (e.g., radial width) of the passageways may decrease in size (e.g., radial width) when moving radially around the circumference of the purge ring until reaching a point (e.g., 180 degrees) in the circumference that is opposite the supply port 420, as previously described. For example, the passageways may gradually decrease in size moving radially away from the purge inlet 420 at 0 degrees. For purposes of illustration, passageways 430B, 430C, 430D, 430E, 430F, 430G, 430H, and 430I may sequentially decrease in size (e.g., radial width), such that passageway 430B has the largest width, and passageway 430I has the smallest width. In one embodiment, because of the symmetrical constraints about the symmetry line and/or plane 440, passageway 430A that is centered at 0 degrees may be smaller in radial width than the adjacent passageway 430B.

FIG. 4D is a graph 465 illustrating the variation in the velocity (e.g., x-axis) of gas with respect to angular position (e.g., y-axis) on a purge ring configured for symmetric distribution of gas around a wafer perimeter, in accordance with one embodiment of the disclosure. As shown, particular, graph 465 shows that there is low variation in the exit flow rate and/or pressure of gas about the inner diameter of the purge ring, or circumference 410 associated with the outlet network 460 of the purge ring 200. That is, the velocity of the gas flow from the outlet network 460 at all points around the circumference is approximately equal. Correspondingly, the pressure of the gas delivered form the outlet network 460 at all points around the circumference is approximately equal. For example, the velocity and/or pressure of the gas at points near the purge inlet 420 located at 0 degrees is approximately equal to the velocity and/or pressure of the gas at points furthest away from the purge inlet (e.g., at 180 degrees).

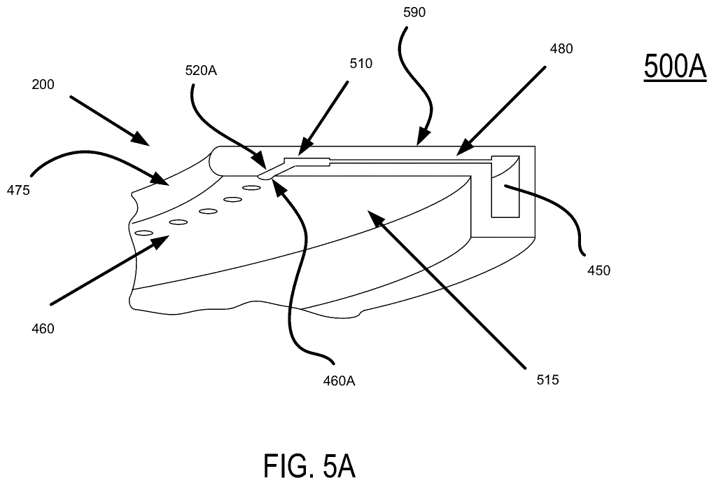

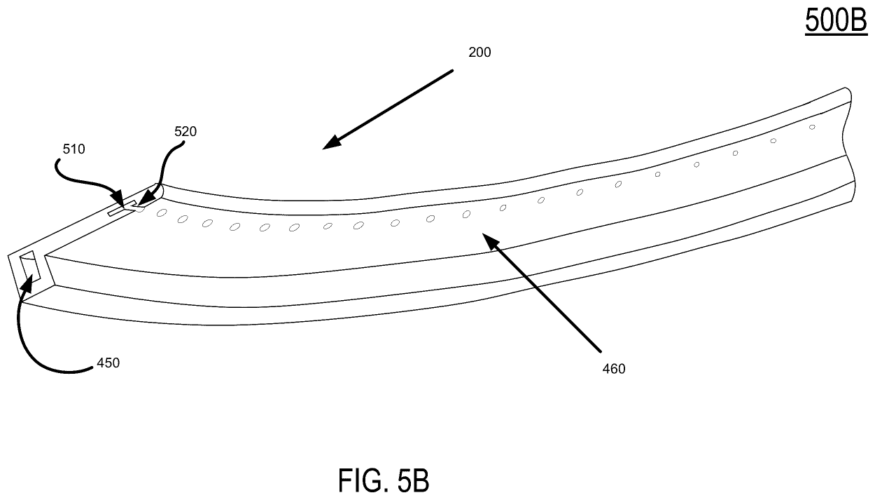

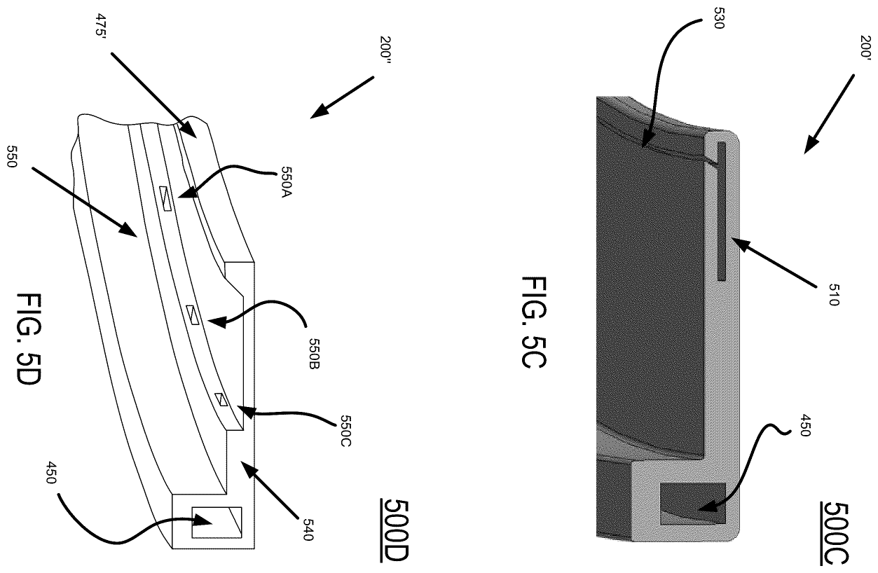

FIG. 5A is an illustration 500A showing a perspective view including a cross-section of a purge ring 200 configured for symmetric distribution of gas (e.g., purge gas, inert gas, nitrogen, N2, etc.) around a wafer perimeter, in accordance with one embodiment of the disclosure. As shown, the purge ring 200 includes an outlet network 460 including a plurality of exit apertures configured for the outflow of gas, wherein the purge ring is configured for radial symmetric flow of gas, such that even and uniform gas flow exits the purge ring at all points around the circumference 410 associated with the outlet network 460.

For example, the purge ring includes an outer channel 450 configured to receive at a purge inlet 420 (not shown) the gas from a gas distribution system. The outer channel is configured to present low fluid resistance to the gas such that the gas reaches pressure equilibrium throughout the outer channel 450 in a first phase of gas distribution before delivery of gas to the distribution volume 480. That is, after reaching equilibrium in the outer channel, the gas leaks to the distribution volume 480 that includes a plurality of passageways and a plurality of channels, as previously described. The passageways and channels, for example in a distribution volume 480) are configured to provide uniform and symmetric radial gas flow to a reservoir 510, wherein the reservoir connects the channels and passageways and/or channels and passageways in a distribution volume 480 to the outlet network 460, in embodiments. In that manner, pressure equilibrium is also achieved in the reservoir 510 when delivering the gas to the outlet network, such as before radial flow of the gas to the outlet network 460. By having uniform gas flow at all points around the distribution volume 480 and/or at all points around the reservoir 510, the gas flow exiting the outlet network 460 provides for a symmetric distribution of gas around a wafer perimeter.

Outlet network 460 may be configured in any manner to provide for the symmetric distribution of gas around a wafer perimeter. In one embodiment, the outlet network includes a plurality of exit apertures in the outlet network, wherein each exit aperture is configured for providing a corresponding portion of the exit flow of the gas. In one embodiment, the outlet network comprises an array of exit apertures. The exit apertures may be in any shape and form, and may include an opening, orifice, exit port, etc. In embodiments, the exit apertures may be distributed symmetrically or asymmetrically around the circumference 410 associated with the outlet network 460. In another embodiment, the plurality of exit apertures is configured on a bottom surface 515 of the purge ring 200.

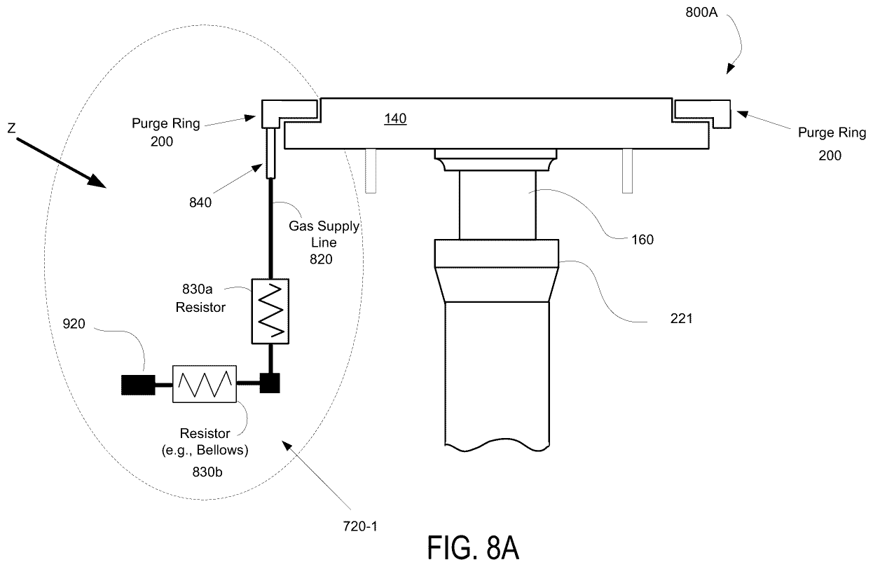

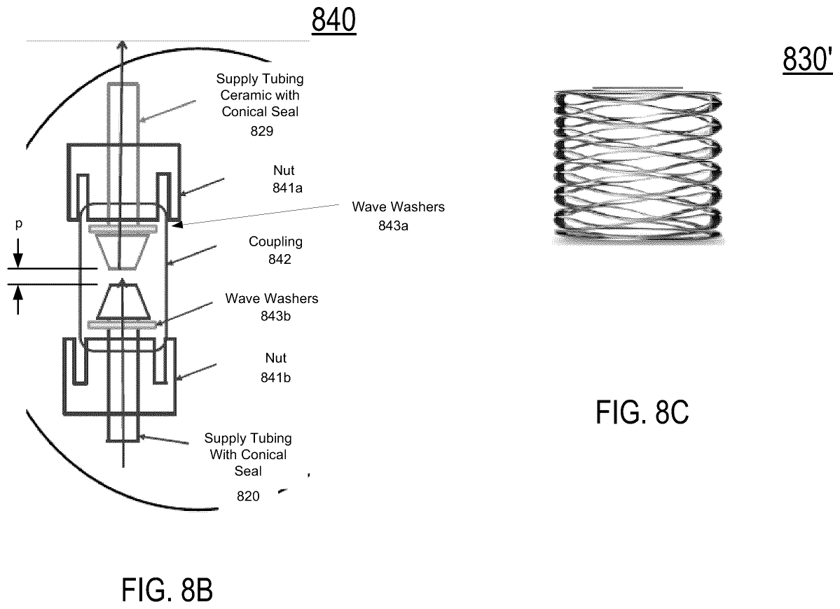

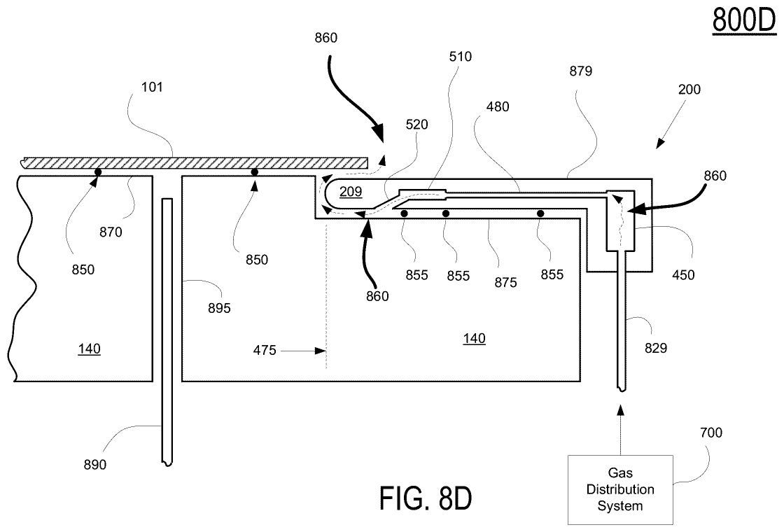

For example, exit aperture 460A is connected to channel 520A which is connected to reservoir 510. In one embodiment, channel 520A is angled to promote the outflow of gas from exit aperture 460A in a direction towards the inner diameter 475 of the purge ring 200. In particular, the outlet network 460 is oriented in a downwards direction such that the channels (including channel 520A) leading to the exit apertures extend laterally inwards when extending from the reservoir 510 towards the inner diameter 475 to connect to corresponding exit apertures, in one embodiment. In that manner, the gas is directed towards the wafer perimeter (e.g., that is located slightly above and overlaps the inner diameter 475 of the purge ring 200 in order to provide for the distribution of gas around a corresponding portion of the wafer perimeter, such as to dilute process gases around the wafer perimeter, as will be further described in relation to FIG. 8D. In other embodiments, the outlet network 460 is oriented in a downwards direction such that the channels (including channel 520A) leading to the exit apertures extend laterally outwards when extending from the reservoir 510 and away from the inner diameter 475 to connect to corresponding exit apertures, in one embodiment. In still other embodiments, the outlet network is oriented in an upwards direction such that the channels extend upwards from the reservoir towards an upper surface 590 to connect to corresponding exit apertures (not shown), wherein the channels may extend laterally inwards towards the inner diameter 475 or outwards away from the inner diameter 475. FIGS. 6A-1 through 6A-4 illustrate different orientations of the channels and exit apertures of the outlet network 460 in various exemplary embodiments. It is understood that other orientations of the channels and exit apertures are supported, though not shown.

FIG. 5B is an illustration 500B showing another perspective view including a cross-section of the purge ring 200 shown in FIG. 5A, in accordance with one embodiment of the disclosure. The cross section may show a region where there is no channel, and no passageway, or where the passageway is configured to fully restrict the flow of purge gas. In particular, reservoir 510 is shown and channel 520 that is angled connects the reservoir 510 to at least one outlet port (e.g., exit aperture) of the outlet network 460.

Reservoir 510 may have a ring shape, annular, annular ring shape, etc., wherein the reservoir 510 has a volume. In one embodiment, the reservoir 510 is continuous, such that the reservoir 510 has an inner volume or channel that continues uninterrupted throughout the purge ring. In another embodiment, the reservoir 510 may be sectioned, such that different sections connect the distribution volume 480 to corresponding portions of the outlet network 460.

FIG. 5C is an illustration 500C providing a perspective view including a cross-section of a purge ring 200′ configured for symmetric distribution of gas (e.g., purge gas, inert gas, nitrogen, N2, etc.) around a wafer perimeter, in accordance with one embodiment of the disclosure. In particular, the purge ring 200′ incudes an outer channel 450 that is connected to a reservoir 510 via channels and passageways. In one embodiment, the outer channel 450 is connected to the reservoir 510 via a distribution volume including channels and passageways. The reservoir 510 connects the channels and passageways to the outlet network that includes one or more continuous channels 530 configured for the outflow of gas. The one or more continuous channels 530 may be configured such that it follows a circumference of the outlet network, such as for purposes of illustration, circumference 410. For example, the outlet network may be one continuous channel around the entire circumference, or may be sectioned into multiple sections of channels configured around the circumference. In one embodiment, at least one of the one or more continuous channels comprises a porous media. The outlet channel 530 provides for uniform and symmetric radial gas flow from the purge ring 200′, such that the gas flow exiting the outlet network provides for a symmetric distribution of gas around a wafer perimeter, as previously described.

FIG. 5D is an illustration 500D showing a perspective view including a cross-section of a purge ring 200′ configured for symmetric distribution of gas (e.g., purge gas, inert gas, nitrogen, N2, etc.) around a wafer perimeter, in accordance with one embodiment of the disclosure. In particular, the purge ring 200″ has an outlet network including a series of outlet ports 550 or exit apertures arranged on an inner ledge 540 that is located proximate to or adjacent to the outer channel 450. The inner ledge may follow and/or be located proximate to the outer channel throughout the purge ring 200′. As shown, the outlet ports 550 are configured for the outflow of gas, in accordance with one embodiment of the disclosure. As shown, the inner ledge 540 includes at least outlet ports 550A, 550B, and 550C. The outlet ports are arranged in such a manner to direct the gas in a direction towards the inner diameter 475′ of the purge ring 200′. In that manner, the gas is directed towards the wafer perimeter (e.g., that is located slightly above and overlaps the inner diameter 475′ of the purge ring 200″ in order to provide for the distribution of purge gas around a corresponding portion of the wafer perimeter

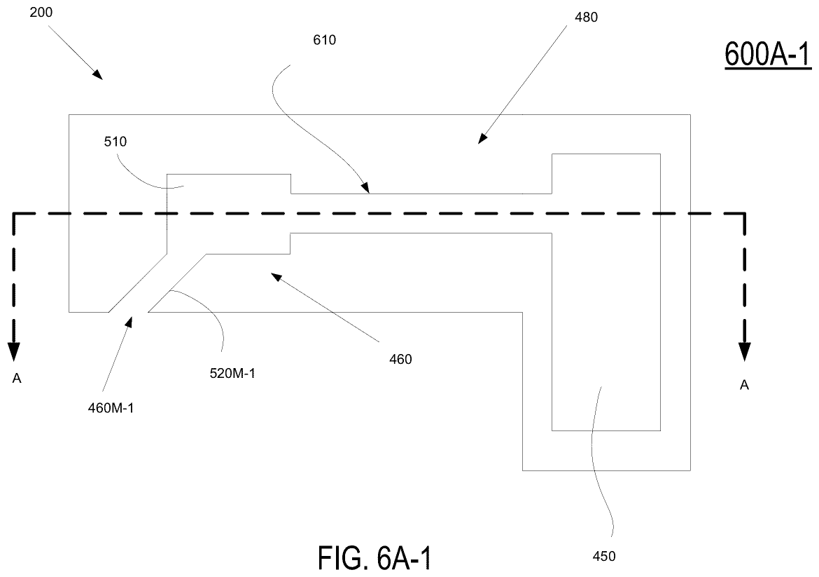

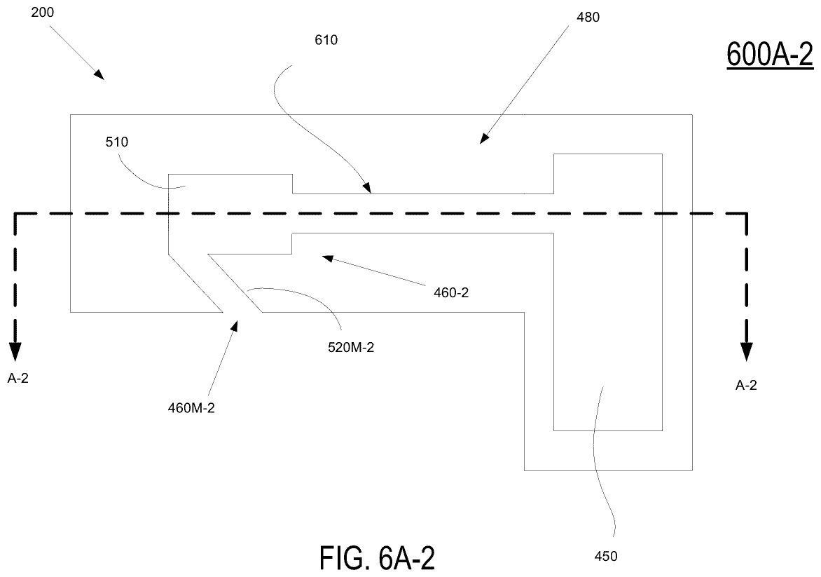

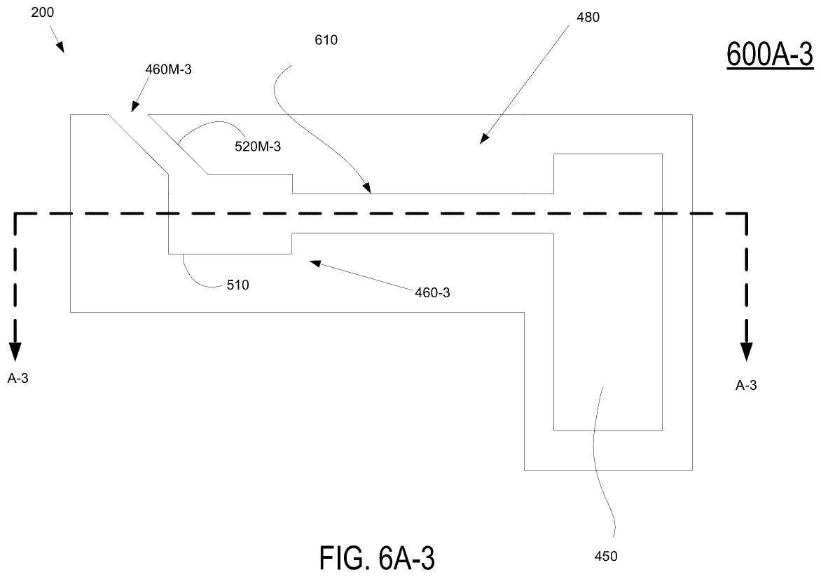

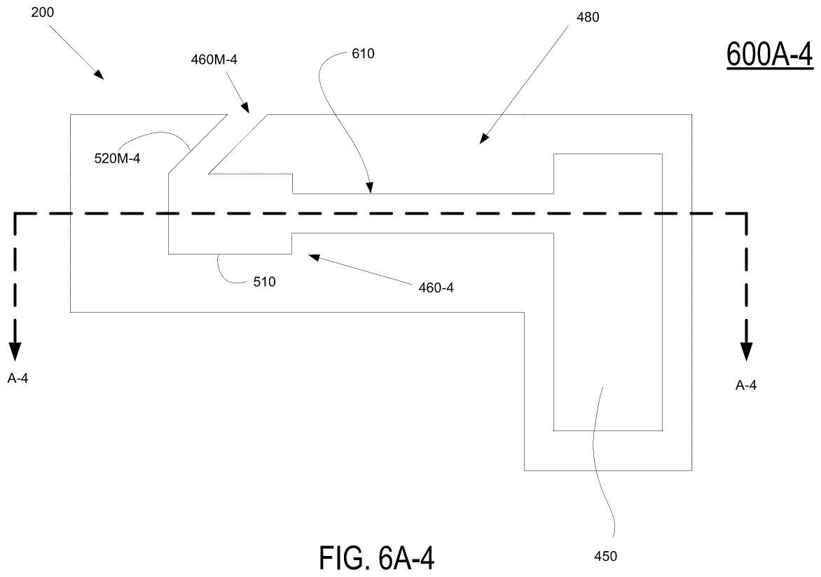

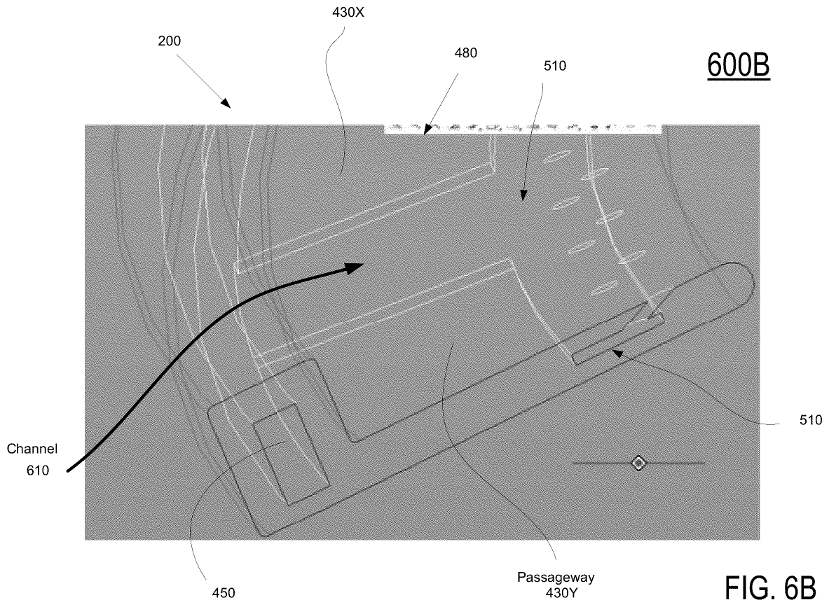

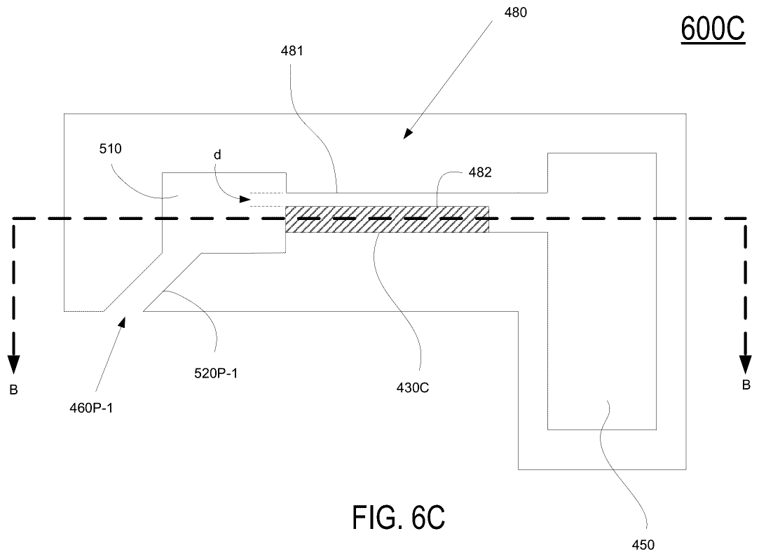

FIG. 6A is a cross-section 600A taken along line A—A of FIG. 4A of a channel 610 in the purge ring 200 previously introduced in at least FIGS. 4A-4B that is configured for symmetric distribution of gas (e.g., purge gas, inert gas, nitrogen, N2, etc.) around a wafer perimeter, in accordance with one embodiment of the disclosure. In one embodiment, the channel 610 is located in a distribution volume 480 that includes channels and passageways. The channel 610 shown in FIG. 6A provides for flow of gas in a radial direction between the outer channel and towards the outlet network 460, as previously described. In particular, channel 610 provides for low fluid resistance to the gas in the radial direction, and provides an unrestricted radial path to the outlet network 460.

As shown, the cross-section 600A of the purge ring 200 includes the outer channel 450 that is configured to provide low fluid resistance circumferentially to the gas that is received at the purge inlet 420. As such, the gas flows circumferentially around the outer channel 450 until reaching pressure equilibrium in a first phase. After reaching the pressure equilibrium, the gas flows and/or leaks radially into the plurality of passageways and a plurality of channels. In some embodiments, the gas flows radially into a distribution volume that includes the passageways and channels. For example, the gas radially flows into the channel 610 and in a direction towards the reservoir 510. Further, the gas flows from the reservoir through the channel 520M-1 of the outlet network 460 and exits the outlet port 460M (e.g., exit aperture). As previously described, outlet network 460 is oriented in a downwards direction such that the channels (including channel 520M-1) leading to the exit apertures (including exit aperture 460M-1) extend downwards and laterally inwards when extending from the reservoir 510 towards the inner diameter 475 to connect to corresponding exit apertures, in one embodiment. It is understood that channel 520M-1 may access reservoir 510 at any location, and that the configuration shown in FIG. 6A-1 is exemplary. The reservoir 510 is configured to reach pressure equilibrium, such that symmetric radial flow of gas is provided throughout the outlet network 460. That is, the outflow of gas from the outlet port 460M-1 is approximately equal to the outflow of gas from another outlet port in the outlet network 460.

FIG. 6A-2 is a cross-section 600A-2 of a channel in a distribution volume of a purge ring configured for symmetric distribution of inert gas around a wafer perimeter, wherein exit channels are configured in a downwards and outwards orientation, in accordance with one embodiment of the disclosure. The line A-2 is similar in positioning of line A—A of FIG. 4A, wherein cross-section 600A-2 shows a different orientation and configuration of outlet network 460. In particular, the outlet network 460-2 is oriented in a downwards direction such that the channels (including channel 520M-2) leading to the exit apertures (including exit aperture 460M-2) extend downwards and laterally outwards when extending from the reservoir 510 away from the inner diameter 475 and towards the outer channel 450 to connect to corresponding exit apertures, in one embodiment. It is understood that channel 520M-2 may access reservoir 510 at any location, and that the configuration shown in FIG. 6A-2 is exemplary.

FIG. 6A-3 is a cross-section of a channel in a distribution volume of a purge ring configured for symmetric distribution of inert gas around a wafer perimeter, wherein exit channels are configured in a upwards and inwards orientation, in accordance with one embodiment of the disclosure. The line A-3 is similar in positioning of line A—A of FIG. 4A, wherein cross-section 600A-3 shows a different orientation and configuration of outlet network 460. In particular, the outlet network 460-3 is oriented in a upwards direction such that the channels (including channel 520M-3) leading to the exit apertures (including exit aperture 460M-3) extend upwards and laterally inwards when extending from the reservoir 510 towards the inner diameter 475 to connect to corresponding exit apertures, in one embodiment. It is understood that channel 520M-3 may access reservoir 510 at any location, and that the configuration shown in FIG. 6A-3 is exemplary.

FIG. 6A-4 is a cross-section of a channel in a distribution volume of a purge ring configured for symmetric distribution of inert gas around a wafer perimeter, wherein exit channels are configured in a upwards and outwards orientation, in accordance with one embodiment of the disclosure. The line A-4 is similar in positioning of line A—A of FIG. 4A, wherein cross-section 600A-2 shows a different orientation and configuration of outlet network 460. In particular, the outlet network 460-2 is oriented in a upwards direction such that the channels (including channel 520M-4) leading to the exit apertures (including exit aperture 460M-4) extend upwards and laterally outwards when extending from the reservoir 510 away from the inner diameter 475 and towards the outer channel 450 to connect to corresponding exit apertures, in one embodiment. It is understood that channel 520M-4 may access reservoir 510 at any location, and that the configuration shown in FIG. 6A-4 is exemplary.

FIG. 6B is a perspective cutaway view 600B including a cross-section of the purge ring 200 previously introduced in at least FIGS. 4A-4B that is configured for symmetric distribution of gas (e.g., purge gas, inert gas, nitrogen, N2, etc.) around a wafer perimeter, in accordance with one embodiment of the disclosure. The cutaway view 600B illustrates the bottom of the purge ring 200. In particular, the outer channel 450 is configured to provide low fluid resistance circumferentially to the gas that is received at the purge inlet 420, as previously described.

After reaching pressure equilibrium in the outer channel 450, the gas flows and/or leaks radially into a plurality of passageways 430 and a plurality of channels. In one embodiment, the gas flows radially into a distribution volume 480 that includes the passageways and channels. For example, passageways 430X and 430Y are located on either side of and adjacent to channel 610. Each of the passageways 430X and 430Y restrict the radial flow of gas through the distribution volume, such that the gas is redirected at least partially towards the channel 610 by those passageways 430X and 430Y. As previously described, channels are configured for flow of gas in the radial direction from the outer channel to the outlet network. In one implementation, the channels provide for unrestricted radial flow of gas through the distribution volume 480 towards the outlet network 460 previously introduced. That is, the passageways provide higher fluid resistance in the radial direction when compared to the fluid resistance in the radial direction presented at the channels. As such, the configuration of passageways and channels are configured to provide even and uniform radial gas flow to the reservoir 510 throughout the purge ring 200.

As previously described, the reservoir 510 is configured to reach pressure equilibrium, such that symmetric radial flow of gas is provided throughout the outlet network 460. For example, the outlet network 460 may include a plurality of exit apertures or outlet ports distributed throughout a circumference 410 of the purge ring 200. As such, the outflow of gas from any exit aperture or outlet port in the outlet network 460 is approximately equal to the outflow of gas from another exit aperture or outlet port in the outlet network.

FIG. 6C is a cross-section 600C taken along line B—B of an exemplary passageway in a purge ring configured for symmetric distribution of gas (e.g., purge gas, inert gas, nitrogen, N2, etc.) around a wafer perimeter, in accordance with one embodiment of the disclosure. In one implementation, the passageway is located in a distribution volume 480 that includes passageways and channels, as previously described. As shown, the cross-section 600C of the purge ring 200 includes the outer channel 450 that is configured to provide low fluid resistance circumferentially to the gas that is received at the purge inlet 420. As such, the gas flows around the outlet channel until reaching pressure equilibrium in a first phase. After reaching the pressure equilibrium, the gas flows and/or leaks radially into the plurality of passageways and a plurality of channels. In one implementation, the gas flows radially into a distribution volume 480 that includes passageways and channels.

In cross-section 600C, the gas flows into the passageway 430C and generally in a direction towards the reservoir 510, wherein passageway 430 is configured with reduced flow of the gas in the radial direction. Passageway 430C is located between channels 2 and 3. The passageway 430C is configured to restrict, divert, redirect, etc. the flow of gas through the distribution volume 480 as the gas flows towards the outlet network 460 previously introduced. In particular, the passageway 430C provides for higher fluid resistance radially to the gas when compared to the fluid resistance presented in a channel, and as such provides a restricted radial path to the outlet network 460 through the passageway 430C. Thereafter, the gas flows from the reservoir through the channel 520P of the outlet network 460 and exits the outlet port 460P. The reservoir 510 is configured to reach pressure equilibrium, such that symmetric radial flow of gas is provided throughout the outlet network 460. That is, the outflow of gas from the exit aperture or outlet port 460P is approximately equal to the outflow of gas from another exit aperture or outlet port in the outlet network 460.

The passageway 430C may be configured to varying degrees of fluid resistance. The passageway may be a solid or porous media having a surface 482 that may be flat (e.g., see passageway 430Y in FIG. 6B). For example, distance “d” between the surface 482 and a top surface 481 may be selectable to provide different values of fluid resistance. A space between the surface 482 and the top surface 481 provides for fluid flow. In general and for purposes of illustration, a greater distance “d” in the space provides lower fluid resistance (low height for the passageway), whereas a lower distance “d” provides for higher fluid resistance (e.g., large height for the passageway), at least in the radial direction. Furthermore, varying the porosity, size and/or shape of the passageway also affects the fluid resistance. For example, instead of having a flat surface to the passageway, the surface 482 of the passageway 430C may be ribbed across the entire surface to increase a surface area, which thereby increases fluid resistance in the corresponding passageway at least in the radial direction. In embodiments of the present disclosure, one or more passageways in the plurality of passageways 430 may be differently configured to provide varying degrees of fluid resistance.

FIG. 7 illustrates a gas distribution system 700 configured for distributing gas with even gas flow to each of the pedestal assemblies of a plurality of stations within a multi-station process chamber, in accordance with one embodiment of the disclosure. The gas distribution system 700 provides balanced gas delivery from station to station, such that a uniform flow of gas is provided to each of the stations (e.g., STN1, STN2, STN3, and STN4) at each of the supply branches. The gas distribution system 700 is configured to operate in extreme conditions, such as high temperature and high pressure presented in a processing chamber.

In one embodiment, each of the pedestal assemblies of a corresponding station includes a purge ring configured for symmetric distribution of gas (e.g., purge gas, inert gas, nitrogen, N2, etc.) around a wafer perimeter, in accordance with one embodiment of the disclosure. As previously described, the purge ring provides symmetric and balanced radial flow with one supply port (e.g., purge inlet 420). In particular, the purge ring is configured to provide variable flow of fluid, for example, to provide radial symmetric flow at all points of an outlet network (e.g., plurality of outlet ports). As such, the radial flow velocity of the gas flow at all points in the outlet network is uniform, in one embodiment. Further, the pressure of the gas flow at all points in the outlet network is uniform, in another embodiment.

In particular, the gas distribution system 700 incudes facilities 760 that provides a source of gas. An ultra high purity (UHP) and high precision pressure regulator 750 is provided to regulate the pressure, such as to provide low pressure. A precision mass flow controller (MFC) 740 is configured to provide controlled low flow and low pressure for the gas. In particular, MFC 740 is pressure insensitive and provides precision low flow MFC for the gas. Also, a UHP two port/two position valve 730 is provided. The facilities 760, the UHP pressure regulator 750, the MFC 740, and UHP two port/two position valve 730 are provided within or connected to a gas delivery structure or conduit 710, such as a flexible gas line or conduit.

In particular, the gas delivery structure or conduit 710 is routed through internal station partition walls 211 of the process chamber, wherein the gas delivery structure 710 provides for the delivery of gas to each of the stations via a corresponding access port (e.g., port 920). For example, each access port corresponds to a supply branch that leads to a corresponding station. As shown, the gas delivery structure 710 includes four supply branches 720-1, 720-2, 720-3, and 720-4. Each of the supply branches is connected to a corresponding access port and configured to deliver the gas to a purge ring of a pedestal assembly in a corresponding station. For example, supply branch 720-1 supplies gas to station 1, supply branch 720-2 supplies gas to station 2, supply branch 720-3 supplies gas to station 3, and supply branch 720-4 supplies gas to station 4. The highlighted area Z is expanded to show components of supply branch 720-1 in FIG. 8A.

FIG. 8A is an illustration showing a partial cross section of a pedestal assembly 800A including a purge ring 200 configured for symmetric distribution of gas (e.g., purge gas, inert gas, nitrogen, N2, etc.) around a wafer perimeter, as previously described, and a supply branch 720-1 in highlight area Z for delivering gas to the purge ring 200, in accordance with one embodiment of the disclosure. Components in FIG. 8A are genericized in order to show the delivery of gas to each station. In particular, pedestal assembly 800A includes a spindle 160. Station connection 221 is configured for seating a spindle in a corresponding station. A rotation mechanism (not shown) may be connected to the spindle 160 for purposes of rotation the pedestal 140. The spindle 160 is connected to the pedestal 140 configured for supporting a substrate, as previously described. Purge ring 200 is located proximate to an outer perimeter of the pedestal 140, wherein the interfacing of the purge ring 200 and pedestal 140 is described more fully below in relation to FIG. 8D.

Highlighted area Z is also shown in FIG. 8A, and provides an expanded view of the supply branch 720-1 that delivers gas to the purge ring 200 from the gas delivery structure 710, previously introduced. In particular, the gas delivery structure 710 includes an access port 920 that may be a three-way connector in one embodiment, with one connection leading to branch 720-1. The gas delivery structure 710 provides high precision flow rates of gas (e.g., controlled low flow and low pressure for the gas), to the access port 920 (e.g., distribution manifold, three way connector, etc.), as previously described. The gas delivery structure 710 may include flexible tubing (e.g., metal, etc.) and connections.

The supply branch 720-1 may include at least one fluid resistor 830 configured to regulate gas flow to the corresponding station. Providing more than one fluid resistor provides for more precise control. In that manner, the gas flow to each of a plurality of stations can be regulated to supply near uniform or approximately equal gas flow to each of the stations, wherein regulation of gas may be provided through fluid resistors of corresponding branches. For example, a first flow resistor 830a and a second flow resistor 830b may be provided in a gas supply line 820 (e.g., conduit) of the supply branch 720-1. A coupling interface 840 provides for interfacing the metal gas supply line 820 to ceramic conduit or tubing that is connected to the ceramic purge ring 200, and is further described in relation to FIG. 8B.

FIG. 8B is an expanded view of a cross section of the coupling interface 840 that tis configured to provide a ceramic to metal transition. In particular, the coupling interface 840 interfaces a metal gas conduit to a ceramic purge ring configured for symmetric distribution of inert gas around a wafer perimeter and a conduit for delivering gas to the purge ring, in accordance with one embodiment of the disclosure. As shown, a supply conduit 829 that is ceramic connects to the purge ring 200 at one end, and connects to a coupler 842 via a conical seal at the other end. In particular, nut 841a and wave washers 843a (e.g., that may be bellows compliant) are used for securing the supply conduit 829 to the coupler 842. Also, a gas supply conduit 820 that is metal connects at one end to an access port (e.g., via the supply branch previously described) that delivers gas. The gas supply conduit 820 connects at the other end to the coupler 842 via a conical seal. In particular, nut 841b (e.g., nickel alloy) and wave washers 843b (e.g., that may be bellows compliant) are used for securing the gas supply line or conduit 820 to the coupler 842.

As shown, distance “p” may be variable between the supply conduits 820 and 829, to provide additional flow control. For instance, the greater the distance “p”, the higher the fluid resistance affecting the flow of gas to the purge ring 200.

FIG. 8C is a cross section of a flow resistor 830′ configured within a conduit for delivering gas to a purge ring 200 that is configured for symmetric distribution of gas (e.g., purge gas, inert gas, nitrogen, N2, etc.) around a wafer perimeter, wherein the flow resistor 830′ may be included within a conduit for delivering gas to the purge ring, in accordance with one embodiment of the disclosure. As shown, the flow resistor 830′ may be in the form of bellows configured to provide fluid resistance.

FIG. 8D is a cross-section of an exemplary pedestal assembly 800D showing the perimeter of pedestal 140 interfacing with a purge ring 200, in accordance with one embodiment of the disclosure. The purge ring 200 receives gas (e.g., purge gas, inert gas, nitrogen, N2, etc.) through supply tubing 829, which is connected to a gas distribution system 700 that includes a gas delivery structure 710 both configured to delivery gas to corresponding station including the purge ring 200. As previously described, the purge ring 200 includes outer channel 450 that is configured to provide low fluid resistance circumferentially to the gas that is received at a purge inlet (e.g., inlet 420) (not shown). As such, the gas flows circumferentially around the outlet channel until reaching pressure equilibrium in a first phase. After reaching the pressure equilibrium, the gas flows and/or leaks radially into a plurality of passageways and a plurality of channels, as previously described. In one implementation, the gas flows radially into a distribution volume 480 that includes passageways and channels, as previously described. For example, the gas flows radially through the passageways and channels in a direction towards the reservoir 510. Further, the gas flows from the reservoir 510 through a channel 520 to an exit aperture or outlet port of an outlet network. The reservoir 510 is configured to reach pressure equilibrium, such that symmetric radial flow of gas is provided throughout the outlet network. That is, the outflow of gas from the outlet network is approximately equal at all points around a circumference associated with the outlet network, in order to provide radial symmetric and uniform flow of gas to a wafer perimeter.

In one embodiment, the purge ring is stationary, such that there is no movement of the purge ring 200, during wafer loading and/or unloading. For example, during wafer delivery, the lift pins 890 move upwards through travel space 895 in order to raise the wafer 101 from the MCAs 850 above the top surface 870 of the pedestal a sufficient distance to allow a robot arm (e.g., end effector) to engage with the wafer for purposes of loading and/or unloading the wafer from the process chamber. In other embodiments, the purge ring is also stationary, such that there is no movement of the purge ring 200, during wafer rotation from station to station. For example, during wafer rotation, the lift pins 890 move upwards through travel space 895 in order to raise the wafer 101 from the MCAs 850 above the top surface 870 of the pedestal a sufficient distance to allow the paddles 225 of the rotation mechanism 220 to engage with the wafer 101 for purposes of indexing wafer to an appropriate station, such that the wafer is rotated from one station to another station in the multi-station process chamber.

The pedestal 140 includes a top surface 870 configured for supporting a wafer 101. Wafer supports or minimum contact areas (MCA) 850 may be used to improve precision mating between surfaces (e.g., top surface 870 and bottom surface of wafer 101) when high precision or tolerances are required, and/or minimal physical contact is desirable to reduce defect risk. The pedestal 140 may include a step (e.g., down step) at the perimeter of the pedestal 140, wherein a top surface 875 of the step may be lower than the top surface 870 of the pedestal used for supporting the wafer. Additional purge ring supports 855 provide for maintaining a controlled distance between the purge ring 200 and the top surface 875 of the step when the purge ring is resting on the purge ring supports 855. Instead of purge ring supports 855, the purge ring 200 may be supported using MCAs that are located on top surface 875 of the step of the pedestal 140.

When the wafer 100 is supported by the MCAs 850 and the purge ring 200 is supported by the purge ring supports 855, then an edge region of the wafer 100 is disposed over an inner portion 209 of the purge ring 200 in some embodiments. That is, the wafer 100 extends beyond an inner diameter 475 of the purge ring 200, and overlaps the inner diameter 475. In one embodiment, the top surface 879 of the purge ring 200 that is resting on purge ring supports 855 of the step may be lower than the top surface 870 of the pedestal used for supporting the wafer. Support of the purge ring at the distance above the top surface 875 of the step, as well as the support of the wafer at a distance above the top surface 870 of the pedestal 140 are tuned to create a vertical separation (e.g., 0.5-10 mm) between the edge region of the wafer and the inner portion 209 of the purge ring 200 (e.g., the top surface 879 near the inner diameter 475). In that manner, the flow 860 of purge gas through the purge ring 200 (e.g., via outer channel 450, through the distribution volume 480, to the reservoir 510, and out through the outlet network) and through a space created between the purge ring 200, pedestal 140, and wafer 1010 is permitted. In particular, the purge gas follows flow 860 around the inner portion 209 of the purge ring 200 and under the edge of the wafer 101 to collect in a volume near the wafer edge in order to dilute process gases at the wafer edge, as previously described. Specifically, the purge gas provides for localized dilution of a plasma sheath around the wafer edge in order to reduce charge buildup at the wafer edge, thereby reducing the probability of electrical discharge or arching from the wafer to the ceramic pedestal during process (e.g., PECVD, ALD, etc.). In another embodiment, the purge gas present around the edge of the wafer 101 creates a positive backflow to limit deposition on the backside of the wafer, especially near the wafer edge (e.g., minimize plasma formation in the gap below the edge of the wafer and above the top surface 879 of the purge ring).

FIG. 9A illustrates a top view of a multi-station processing tool 250, wherein four processing stations are provided, and shows a gas distribution system for distributing gas (e.g., purge gas, inert gas, nitrogen, N2, etc.) with even gas flow to pedestal assemblies of each of the stations, in accordance with one embodiment of the disclosure. The multi-station processing tool 250 was previously introduced in FIG. 2A, and the discussion of related components (e.g., similarly numbered components) in relation to FIG. 2A is relevant for FIG. 9A, and is not repeated for purposes of clarity and brevity.

As shown in FIG. 9A, gas delivery structure 710 (e.g., flexible conduit) is routed through internal station partition walls 211 of the process chamber 250, such as through corresponding openings 210. In that manner, the gas delivery structure or conduit 710 is present in each station, and can be accessed for delivery of gas to each of the stations. In particular, the gas delivery structure 710 provides for the delivery of gas to each of the stations via a corresponding access port (e.g., port 920), and corresponding supply branch (e.g., 720-1, 720-2, 720-3, and 720-4). Each of the supply branches is configured to deliver gas to a corresponding purge ring of a corresponding pedestal assembly in a corresponding station, wherein each purge ring receives the gas at a corresponding purge inlet 420.

FIG. 9B illustrates a top view of chamber inserts 910a and 910b of a multi-station processing tool (e.g., tool 250) having four processing stations, in accordance with one embodiment of the disclosure. As shown, the gas delivery structure or conduit 710 of FIG. 9A is routed through openings 210 in station partition walls 211 of the multi-station processing tool or chamber. In particular, each of the station partition walls 211 may include a pair of inserts 910a and 910b. Further, each pair of inserts 910a and 910b is located proximate to a corresponding exterior wall of the chamber. Also, each pair of inserts 910a and 910b includes openings 210 that may be used for routing the gas delivery structure 710 between stations. In that manner, the gas delivery structure 710 is present in each of the stations for purposes of gas delivery.

FIG. 9C illustrates a bottom view of chamber inserts 910a and 910b shown in FIG. 9B of a multi-station processing tool (e.g., tool 250) having four processing stations, in accordance with one embodiment of the disclosure. In the bottom view of chamber inserts of FIG. 9C, openings 210 in the station partition walls 211 are exposed. As previously described, the gas distribution structure or conduit 710 is routed through openings 210 in station partition walls 211 (e.g., via openings 210 of the chamber inserts 910a and 910b) of the multi-station chamber 250.

In particular, gas distribution structure or conduit 710 is configured for distributing the gas with even gas flow uniformly to pedestal assemblies of each of a plurality of stations. As shown, a portion of the gas distribution structure 710 that is included within a station may include one or more compression fittings 925 joining two different metal pieces of conduit and an access port 920 configured to provide gas to a corresponding station. For example, FIG. 9C shows the gas distribution structure 710 being routed through station 1, wherein access port 920 is connected to the gas distribution structure 710 and to a purge inlet 420 of the purge ring 200, such as through branch 720-1. The purge ring 200 is configured to provide for radial symmetric and uniform gas flow from an outlet network (e.g., outlet ports), such that an even distribution of purge gas is provided at the wafer edge during processing, as previously described.

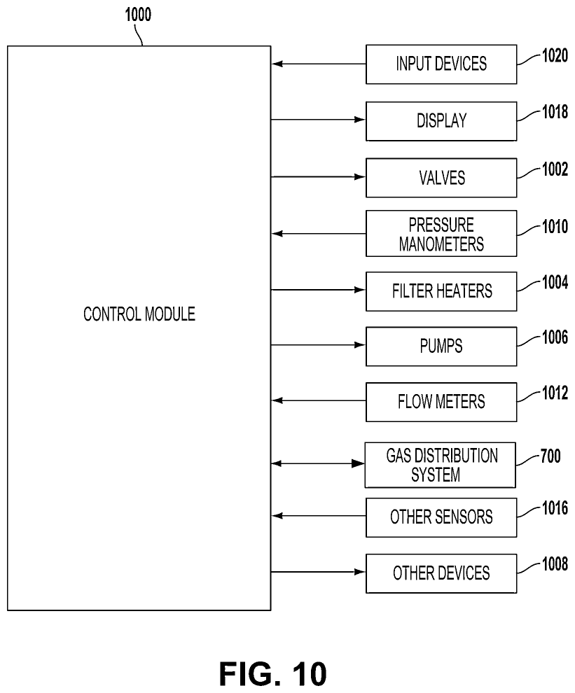

FIG. 10 shows a control module 1000 for controlling the systems described above. For instance, the control module 1000 may include a processor, memory and one or more interfaces. The control module 1000 may be employed to control devices in the system based in part on sensed values. For example only, the control module 1000 may control one or more of valves 1002, filter heaters 1004, pumps 1006, gas distribution system 700, and other devices 1008 based on the sensed values and other control parameters. The control module 1000 receives the sensed values from, for example only, pressure manometers 1010, flow meters 1012, temperature sensors 1014, and/or other sensors 1016. The control module 1000 may also be employed to control process conditions during precursor delivery and deposition of the film. The control module 1000 will typically include one or more memory devices and one or more processors.

The control module 1000 may control activities of the precursor delivery system and deposition apparatus. The control module 1000 executes computer programs including sets of instructions for controlling process timing, delivery system temperature, and pressure differentials across the filters, valve positions, mixture of gases, chamber pressure, chamber temperature, substrate temperature, RF power levels, substrate chuck or pedestal position, delivery of purge gasses, and other parameters of a particular process. The control module 1000 may also monitor the pressure differential and automatically switch vapor precursor delivery from one or more paths to one or more other paths. Other computer programs stored on memory devices associated with the control module 1000 may be employed in some embodiments.

Typically there will be a user interface associated with the control module 1000. The user interface may include a display 1018 (e.g., a display screen and/or graphical software displays of the apparatus and/or process conditions), and user input devices 1020 such as pointing devices, keyboards, touch screens, microphones, etc.

Computer programs for controlling delivery of precursor, deposition and other processes in a process sequence can be written in any conventional computer readable programming language: for example, assembly language, C, C++, Pascal, Fortran or others. Compiled object code or script is executed by the processor to perform the tasks identified in the program.

The control module parameters relate to process conditions such as, for example, filter pressure differentials, process gas composition and flow rates, purge gas flow rates, temperature, pressure, plasma conditions such as RF power levels and the low frequency RF frequency, cooling gas pressure, and chamber wall temperature.

The system software may be designed or configured in many different ways. For example, various chamber component subroutines or control objects may be written to control operation of the chamber components necessary to carry out the inventive processes, including the delivery of purge gas. Examples of programs or sections of programs for this purpose include substrate positioning code, process gas control code, purge gas control code, pressure control code, heater control code, and plasma control code.

A substrate positioning program may include program code for controlling chamber components that are used to load the substrate onto a pedestal or chuck and to control the spacing between the substrate and other parts of the chamber such as a gas inlet and/or target. A process gas control program may include code for controlling gas composition and flow rates and optionally for flowing gas into the chamber prior to deposition in order to stabilize the pressure in the chamber. Purge gas control program may include code for controlling the delivery of purge gas. A filter monitoring program includes code comparing the measured differential(s) to predetermined value(s) and/or code for switching paths. A pressure control program may include code for controlling the pressure in the chamber by regulating, e.g., a throttle valve in the exhaust system of the chamber. A heater control program may include code for controlling the current to heating units for heating components in the precursor delivery system, the substrate and/or other portions of the system. Alternatively, the heater control program may control delivery of a heat transfer gas such as helium to the substrate chuck.

Examples of sensors that may be monitored during deposition include, but are not limited to, mass flow control modules, pressure sensors such as the pressure manometers 1010, and thermocouples located in delivery system, the pedestal or chuck, and state sensors 1020. Appropriately programmed feedback and control algorithms may be used with data from these sensors to maintain desired process conditions. The foregoing describes implementation of embodiments of the disclosure in a single or multi-chamber semiconductor processing tool.

In some implementations, a controller is part of a system, which may be part of the above-described examples. Such systems can comprise semiconductor processing equipment, including a processing tool or tools, chamber or chambers, a platform or platforms for processing, and/or specific processing components (a substrate pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, delivery of purge gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, substrate transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor substrate or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” of all or a part of a fab host computer system, which can allow for remote access of the substrate processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet.

The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, a plasma enhanced chemical vapor deposition (PECVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

Although the foregoing embodiments have been described in some detail for purposes of clarity of understanding, it will be apparent that certain changes and modifications can be practiced within the scope of the appended claims. Accordingly, the present embodiments are to be considered as illustrative and not restrictive, and the embodiments are not to be limited to the details given herein, but may be modified within their scope and equivalents of the claims.

1. A purge ring, comprising:
a supply port configured for receiving gas;
an outer channel connected to the supply port;
an outlet network configured for an exit flow of the gas proximate to an inner diameter of the purge ring;
a plurality of channels configured for flow of the gas in a radial direction from the outer channel to the outlet network;
a plurality of passageways configured for reduced flow of the gas in the radial direction between the outer channel and the outlet network,
wherein the plurality of channels and the plurality of passageways are configured for providing a uniform pressure of the exit flow of the gas across a circumference of the outlet network.

2. The purge ring of claim 1,
wherein the outer channel is configured to achieve pressure equilibrium before radial flow of the gas to the outlet network occurs.

3. The purge ring of claim 1, further comprising:
a distribution volume connecting the outer channel and the outlet network, the distribution volume including the plurality of channels and the plurality of passageways.

4. The purge ring of claim 3, further comprising:
a reservoir connecting the distribution volume to the outlet network, and configured to achieve pressure equilibrium before radial flow of the gas to the outlet network occurs.

5. The purge ring of claim 1,
wherein a first radial width of a first channel centered at a first radial distance from the purge ring inlet is larger than a second radial width of a second channel centered at a second radial distance that is closer to the purge ring inlet.

6. The purge ring of claim 1,
wherein a first radial width of a first passageway centered at a first radial distance from the purge ring inlet is smaller than a second radial width of a second passageway centered at a second radial distance that is closer to the purge ring inlet.

7. The purge ring of claim 1, wherein a passageway in the plurality of passageways comprises a porous media.

8. The purge ring of claim 1, wherein the outlet network includes an array of exit apertures, each exit aperture configured for providing a corresponding portion of the exit flow of the gas.

9. The purge ring of claim 8, wherein exit apertures in the array of exit apertures are distributed symmetrically around the circumference of the outlet network.

10. The purge ring of claim 8, wherein the array of exit apertures is configured on a bottom surface of the purge ring.

11. The purge ring of claim 1, wherein the outlet network includes one or more continuous channels configured about the circumference.

12. The purge ring of claim 11, wherein at least one continuous channel comprises a porous media.

13. A pedestal assembly of a process chamber, the pedestal assembly comprising:
a pedestal for supporting a substrate;
a purge ring configured for placement about a periphery of the pedestal, the purge ring including:
a supply port configured for receiving gas;
an outer channel connected to the supply port;
an outlet network configured for an exit flow of the gas proximate to an inner diameter of the purge ring;
a plurality of channels configured for flow of the gas in a radial direction from the outer channel to the outlet network;
a plurality of passageways configured for reduced flow of the gas in the radial direction between the outer channel and the outlet network,
wherein the plurality of channels and the plurality of passageways are configured for providing a uniform pressure of the exit flow of the gas across a circumference of the outlet network.

14. The pedestal assembly of claim 13, wherein the purge ring is configured to sit below the substrate.

15. The process chamber of claim 13,
wherein in the purge ring the outer channel is configured to achieve pressure equilibrium before radial flow of the gas to the outlet network occurs.

16. The process chamber of claim 13,
wherein the purge ring comprises a distribution volume connecting the outer channel and the outlet network, the distribution volume including the plurality of channels and the plurality of passageways.

17. The process chamber of claim 16,
the purge ring further comprising a reservoir connecting the distribution volume to the outlet network, and configured to achieve pressure equilibrium before radial flow of the gas to the outlet network occurs.

18. The process chamber of claim 13,
wherein in the purge ring a first radial width of a first channel centered at a first radial distance from the purge ring inlet is larger than a second radial width of a second channel centered at a second radial distance that is closer to the purge ring inlet.

19. The process chamber of claim 13,
wherein in the purge ring a first radial width of a first passageway centered at a first radial distance from the purge ring inlet is smaller than a second radial width of a second passageway centered at a second radial distance that is closer to the purge ring inlet.

20. The process chamber of claim 13,
wherein in the purge ring a passageway in the plurality of passageways comprises a porous media.

21. The process chamber of claim 13, wherein in the purge ring the outlet network includes an array of exit apertures, each exit aperture configured for providing a corresponding portion of the exit flow of the gas.

22. The process chamber of claim 21, wherein in the purge ring exit apertures in the array of exit apertures are distributed symmetrically around the circumference of the outlet network.

23. The process chamber of claim 21, wherein in the purge ring the array of exit apertures is configured on a bottom surface of the purge ring.

24. The process chamber of claim 13, wherein in the purge ring the outlet network includes one or more continuous channels configured about the circumference.

25. The process chamber of claim 16, wherein at least one continuous channel comprises a porous media.

26. A process chamber, the process chamber including:
a plurality of stations, each station including a pedestal assembly, each pedestal assembly including:
a pedestal for supporting a substrate;
a purge ring configured for placement about a periphery of the pedestal, the purge ring including:
a supply port configured for receiving gas;
an outer channel connected to the supply port;
an outlet network configured for an exit flow of the gas proximate to an inner diameter of the purge ring;
a plurality of channels configured for flow of the gas in a radial direction from the outer channel to the outlet network;
a plurality of passageways configured for reduced flow of the gas in the radial direction between the outer channel and the outlet network,
wherein the plurality of channels and the plurality of passageways are configured for providing a uniform pressure of the exit flow of the gas across a circumference of the outlet network; and
a gas distribution system for distributing the gas with even gas flow to pedestal assemblies of each of the plurality of stations.

27. The process chamber of claim 26, further comprising:
a gas delivery structure that is routed through station partition walls of the process chamber, the gas delivery structure providing for the delivery of the gas to each of the plurality of stations via a corresponding access port in the gas delivery structure for connecting the gas delivery structure to a corresponding pedestal assembly of a corresponding station via a corresponding conduit;
at least one flow resistor in the corresponding conduit to regulate gas flow to the corresponding station such that the gas flow to each of the plurality of stations is approximately equal.

28. The process chamber of claim 27, wherein the at least one flow resistor includes a first flow resistor and a second flow resistor configured in the corresponding conduit.

29. The process chamber of claim 26, wherein the purge ring is configured to sit below the substrate.

30. The process chamber of claim 26,
wherein in the purge ring the outer channel is configured to achieve pressure equilibrium before radial flow of the gas to the outlet network occurs.

31. The process chamber of claim 26,
wherein the purge ring comprises a distribution volume connecting the outer channel and the outlet network, the distribution volume including the plurality of channels and the plurality of passageways.

32. The process chamber of claim 31,
the purge ring further comprising a reservoir connecting the distribution volume to the outlet network, and configured to achieve pressure equilibrium before radial flow of the gas to the outlet network occurs.

33. The process chamber of claim 26,
wherein in the purge ring a first radial width of a first channel centered at a first radial distance from the purge ring inlet is larger than a second radial width of a second channel centered at a second radial distance that is closer to the purge ring inlet.

34. The process chamber of claim 26,
wherein in the purge ring a first radial width of a first passageway centered at a first radial distance from the purge ring inlet is smaller than a second radial width of a second passageway centered at a second radial distance that is closer to the purge ring inlet.

35. The process chamber of claim 26,
wherein in the purge ring a passageway in the plurality of passageways comprises a porous media.

36. The process chamber of claim 26, wherein in the purge ring the outlet network includes an array of exit apertures, each exit aperture configured for providing a corresponding portion of the exit flow of the gas.

37. The process chamber of claim 36, wherein in the purge ring exit apertures in the array of exit apertures are distributed symmetrically around the circumference of the outlet network.

38. The process chamber of claim 36, wherein in the purge ring the array of exit apertures is configured on a bottom surface of the purge ring.

39. The process chamber of claim 26, wherein in the purge ring the outlet network includes one or more continuous channels configured about the circumference.

40. The process chamber of claim 39, wherein at least one continuous channel comprises a porous media.
